(19) United States
(12) Patent Application Publication
(10) Pub. No.: US 2009/0170230 A1
(43) Pub. Date: Jul. 2, 2009

(54) MANUFACTURING METHOD OF DISPLAY APPARATUS AND MANUFACTURING APPARATUS

(75) Inventors: Takashi KIDU, Tokyo (JP); Tomoko OZAKI, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: CASIO COMPUTER CO., LTD., Tokyo (JP)

(21) Appl. No.: 12/343,966

(22) Filed: Dec. 24, 2008

(30) Foreign Application Priority Data
Dec. 28, 2007 (JP) 2007-340226

(51) Int. Cl. H01L 21/02; B05C 5/00

(52) U.S. Cl. 438/35; 118/314; 257/E21.002

(57) ABSTRACT

A manufacturing method including applying a light emitting material solution for forming a light emitting function layer of the light emitting elements each of which has any one of a plurality of luminescent colors which carry out a color display arranged along a plurality of rows and along a plurality of columns on a substrate to a light emitting element forming region on the substrate in which the light emitting elements of a plurality of columns are formed, in an order that the light emitting material solution is not continuously applied to the light emitting element forming regions in adjacent columns among the plurality of columns and in an applying amount which is set so as to correspond to each of the luminescent colors.

### BACKGROUND OF THE INVENTION

1. Field of the Invention

The present invention relates to a manufacturing method of a display apparatus and a manufacturing apparatus for carrying out the manufacturing method, and particularly to a manufacturing method and a manufacturing apparatus of a display apparatus comprising a display pixel having a light emitting element such as organic electroluminescence element and the like.

2. Description of Related Art

In recent years, there is known a display device applying a display panel (organic EL display panel) in which organic electroluminescence elements (hereinafter, abbreviated as “organic EL element”) are two-dimensionally arranged as a display device of electronic devices such as a cell phone, a portable music player and the like. In particular, the organic EL display panel which applies the active matrix drive method has good display characteristics such that the display response speed is fast and the visual field angle dependency is small comparing to a widely used liquid crystal display apparatus. Further, the organic EL display panel which applies the active matrix drive method has an apparatus structural feature that the backlight is not needed unlike the liquid display apparatus. Therefore, the organic EL display panel which applies the active matrix drive method is anticipated to be applied to various types of electronic devices in future.

As it is well know, the organic EL element has an element structure in which an anode (positive electrode) electrode, the organic ELE layer (light emitting function layer) and a cathode (negative electrode) electrode are orderly layered on one surface side of a substrate such as a glass substrate or the like, in an outline. Further, light (excitation light) is emitted based on energy generated when the injected holes and electrons rejoin in the organic EL layer by applying positive voltage to the anode electrode and by applying negative voltage to the cathode electrode so as to exceed the light emitting threshold in the organic EL layer.

Here, there is known a light emitting structure of top emission type in which light is emitted in one surface side of the substrate and a light emitting structure of bottom emission type in which light is emitted in the other surface side of the substrate by forming either one of a pair of electrodes (anode electrode, cathode electrode) formed so as to oppose to one another via the organic EL layer with an electrode material having light transparency characteristic and the other of the pair of electrodes with an electrode material having light reflecting characteristic. In the display panel of top emission type has a light emitting structure in which the light emitted in the light emitting element provided in one surface side is emitted in the one surface side without transmitting the substrate. On the other hand, the display panel of bottom emission type has a light emitting structure in which the light emitted in the light emitting element is emitted in the other surface side by transmitting through the substrate.

However, in the display panel having the above described light emitting structure, the light emitted in the light emitting layer is directly emitted in the visual field side (one surface side or the other surface side of substrate) via the electrode having a light transparency characteristic and is reflected at the electrode having a light reflecting characteristic, and the reflected light is emitted to the visual field side via the light emitting layer and the electrode having a light transparency characteristic. In such way, a light path difference of film thickness occurs between the emitted light which is directly emitted in the visual field side and the emitted light which is emitted in the visual field side after being reflected at the electrode having a light reflecting characteristic. Further, a shifting in chromaticity and dispersion in light emitting brightness (emission intensity) due to the interference effect by the light path difference occur, and deterioration in the display characteristics such as running, blurring and the like of the image occurs.

### SUMMARY OF THE INVENTION

The present invention relates to a manufacturing method of a display apparatus comprising a display pixel having a light emitting element and to a manufacturing apparatus for carrying out the manufacturing method. There is an advantage that the shifting in chromaticity and dispersion in light emitting brightness can be suppressed and that the display apparatus having good display characteristic without blot and blur in the image can be manufactured.

To obtain the above advantage, a manufacturing method of a display apparatus of the present invention is a manufacturing method of a display apparatus in which a plurality of display pixels comprising light emitting elements each of which has any one of a plurality of luminescent colors which carry out a color display are arranged along a plurality of rows and along a plurality of columns on a substrate, and the manufacturing method comprises a step of applying a light emitting material solution for forming a light emitting function layer of the light emitting elements having each of the luminescent colors to a light emitting element forming region on the substrate, the step of applying the light emitting material solution includes a step of applying the light emitting material solution in which the light emitting elements of a plurality of columns are formed, in an order that the light emitting material solution is not continuously applied to the light emitting element forming regions in adjacent columns among the plurality of columns and in an applying amount which is set so as to correspond to each of the luminescent colors.

To obtain the above advantage, an manufacturing apparatus of the present invention is a manufacturing apparatus for manufacturing a display apparatus in which a plurality of display pixels comprising light emitting elements each of which has any one of a plurality of luminescent colors which carry out a color display are arranged along a plurality of rows and along a plurality of columns on a substrate, and the manufacturing apparatus comprises an applying device having at least one nozzle for discharging a light emitting material solution which forms a light emitting function layer of light emitting elements of each of the luminescent colors and a moving device for moving either one of the applying device or the substrate in a row direction or in a column direction of the substrate, wherein the moving device moves the applying device in the row direction and moves the applying device to each columns which are spaced apart among the plurality of columns on the substrate and moves the applying device along an extending direction of each column, the applying device discharge the light emitting material solution from the nozzle in a discharging amount which is set so as to correspond to each of the luminescent colors to apply the light emitting material solution to a light emitting element forming regions of each column in predetermined applying order while moving along an extending direction of each column by the moving device, said applying order is set in an order that the light emitting material solution is not continuously applied to the light emitting element forming regions in adjacent columns among the plurality of columns.

### BRIEF DESCRIPTION OF THE DRAWINGS

The above and other objects, advantages and features of the present invention will become fully understood from the detailed description given hereinbelow and the appended drawings which are given by way of illustration only, and thus are not intended as a definition of the limits of the present invention, and wherein:

FIG. 1 is a schematic plan diagram showing an example of arrangement of pixels of a display panel which is applied in the display apparatus according to the present invention;

FIG. 2 is a diagram of an equivalent circuit showing an example of a circuit structure of each display pixel which is two-dimensionally arranged in the display panel of the display apparatus according to the present invention;

FIG. 3 is a diagram showing an example of a plan layout of a display pixel which can be applied in the display apparatus (display panel) according to the present invention;

FIG. 4 is a cross sectional diagram showing a cross section surface cut along the line IVA-IVA in FIG. 3;

FIGS. 5A and 5B are cross sectional diagrams showing cross section surfaces cut along the lines VB-VB and VC-VC in FIG. 3;

FIGS. 6A, 6B and 6C are process cross sectional diagrams showing an example of a manufacturing method of the display apparatus (display panel) according to the embodiment (part 1);

FIGS. 7A and 7B are process cross sectional diagrams showing an example of a manufacturing method of the display apparatus (display panel) according to the embodiment (part 2);

FIGS. 8A and 8B are process cross sectional diagrams showing an example of a manufacturing method of the display apparatus (display panel) according to the embodiment (part 3);

FIG. 9 is a process cross sectional diagram showing an example of a manufacturing method of the display apparatus (display panel) according to the embodiment (part 4);

FIG. 10 is a process cross sectional diagram showing an example of a manufacturing method of the display apparatus (display panel) according to the embodiment (part 5);

FIGS. 11A and 11B are diagrams for explaining a film forming process of a hole transporting layer by the film forming process and the manufacturing apparatus of the first configuration in the manufacturing method of the display apparatus (display panel) according to the embodiment (part 1);

FIGS. 12A and 12B are diagrams showing an example of a structure of the manufacturing apparatus for carrying out the first configuration of the manufacturing method of the display apparatus according to the embodiment;

FIGS. 13A and 13B are diagrams for explaining a film forming process of a hole transporting layer by the film forming process and the manufacturing apparatus of the first configuration in the manufacturing method of the display apparatus (display panel) according to the embodiment (part 2);

FIGS. 14A and 14B are diagrams for explaining a film forming process of an electron transporting light emitting layer by the film forming process and the manufacturing apparatus of the first configuration in the manufacturing method of the display apparatus (display panel) according to the embodiment (part 1);

FIGS. 15A and 15B are diagrams for explaining a film forming process of an electron transporting light emitting layer by the film forming process and the manufacturing apparatus of the first configuration in the manufacturing method of the display apparatus (display panel) according to the embodiment (part 2);

FIGS. 16A and 16B are diagrams for explaining a film forming process of a hole transporting layer by the film forming process and the manufacturing apparatus of the second configuration in the manufacturing method of the display apparatus (display panel) according to the embodiment;

FIGS. 17A and 17B are diagrams showing an example of a structure of the manufacturing apparatus for carrying out the second configuration of the manufacturing method of the display apparatus according to the embodiment;

FIGS. 18A and 18B are schematic diagrams showing a test result of effect in a manufacturing method (film forming process of organic EL layer) of the display apparatus according to the embodiment;

FIGS. 19A and 19B are a schematic diagram showing an example (experimental model) of an element structure of an organic EL element formed in the display apparatus (display panel) according to the embodiment and a diagram for explaining an interference effect;

FIGS. 20A and 20B are chromaticity diagrams showing a relation between film thickness of the hole transporting layer and the chromaticity in the organic EL element which emits blue light formed in the display apparatus (display panel) according to the embodiment (part 1);

FIGS. 21A and 21B are chromaticity diagrams showing a relation between film thickness of the hole transporting layer and the chromaticity in the organic EL element which emits blue light formed in the display apparatus (display panel) according to the embodiment (part 2);

FIGS. 22A and 22B are chromaticity diagrams showing a relation between film thickness of the hole transporting layer and the chromaticity in the organic EL element which emits green light and red light formed in the display apparatus (display panel) according to the embodiment; and

FIG. 23 is a chromaticity diagram showing a relation between film thickness of the hole transporting layer and the luminescent chromaticity in the organic EL element formed in the display apparatus (display panel) according to the embodiment.

### DESCRIPTION OF THE PREFERRED EMBODIMENTS

Hereinafter, a display apparatus and a manufacturing method of the display apparatus according to the present invention will be described in detail based on embodiments shown in diagrams.

### <Display Panel>

First, the display panel (organic EL display panel) and the display pixel which are applied in the display apparatus according to the present invention will be described.

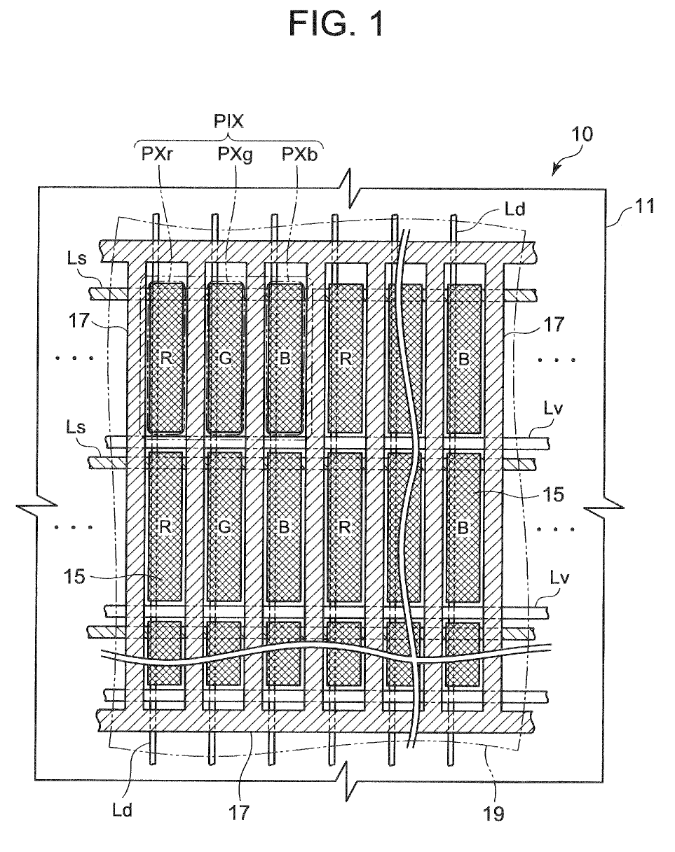

FIG. 1 is a schematic planar diagram showing an example of an arrangement of pixels of the display panel which is applied in the display apparatus according to the present invention.

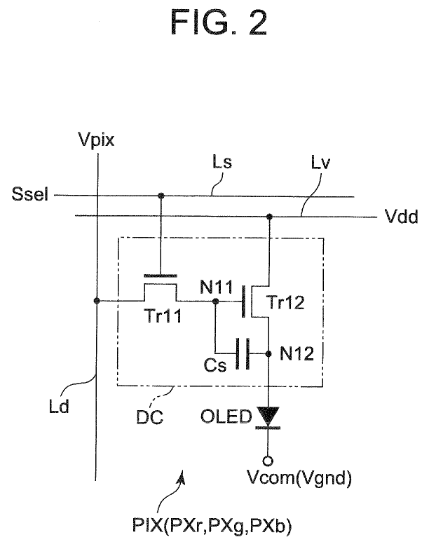

FIG. 2 is a diagram of an equivalent circuit showing an example of a circuit structure of each display pixel (light emitting element and pixel drive circuit) which is two-dimensionally arranged in the display panel of the display apparatus according to the present invention.

Here, in the plan view shown in FIG. 1, only the relation between the disposition of the pixel electrode provided in each display pixel and the dispositional structure of each wiring layer and the dispositional relation between the disposition of the pixel electrode provided in each display pixel and the bank (partition wall) to define the forming region of each display pixel when the display panel is seen from the visual field side (one surface side; forming side of organic EL element) are shown for convenience of explanation, and the transistors and the like in the pixel drive circuit shown in FIG. 2 which are provided in each display pixel in order to drive the organic EL element of each display pixel so as to emit light are omitted from the drawing.

Further, in FIG. 1, hatchings are conveniently carried out in order to clearly shown the dispositions of the pixel electrode, each wiring layers and the bank.

As shown in FIG. 1, the display apparatus (display panel 10) according to the present invention comprises a plurality of select lines Ls disposed in a row direction (left-right direction in drawing), a plurality of power voltage lines (for example, anode lines) Lv disposed in a row direction so as to be parallel to the select lines Ls and a plurality of data lines Ld disposed in a column direction (top-down direction in drawing) orthogonal to the select lines Ls and the power voltage lines Lv on one surface side of the insulative substrate 11 such as a glass substrate or the like. Further, each of the display pixels PIX (sub pixels PXr, PXg and PXb) are disposed in a region including each of the intercepts of the select lines Ls and the data lines Ld.

Here, the display apparatus comprising the above display panel 10 corresponds to color display. In such case, as shown in FIG. 1, each of the sub pixels (hereinafter, conveniently called “color pixel”) PXr, PXg and PXb of three colors of red (R), green (G) and blue (B) are repeatedly arranged in the row direction (left-right direction in drawing) and a plurality of color pixels PXr, PXg or PXb which are in the same color are arranged in the column direction (top-down direction in drawing) for example. In such case, one display pixel PIX is formed by having the color pixels PXr, PXg and PXb of three colors of RGB which are adjacent in the row direction (left-right direction in drawing) as one group.

Moreover, the display panel 10 shown in FIG. 1 comprises a bank (partition wall) 17 disposed so as to protrude from one surface side of the insulative substrate 11 by having a planar pattern of like a fence shape or like a lattice shape. The pixel forming region (in particular, forming region of organic EL element of each color pixels) of a plurality of color pixels PXr, PXg or PXb which are in the same color arranged in the column direction is defined by the bank 17. Further, in the pixel forming region of each of the color pixels PXr, PXg and PXb, the pixel electrode (for example, anode electrode; first electrode) 15 is formed.

As shown in FIG. 2, each of the color pixels PXr, PXg and PXb of the display pixel PIX have a circuit structure comprising the pixel drive circuit DC having a plurality of transistors (for example, amorphous silicon thin film transistor or the like) on the insulative substrate 11 and the organic EL element (light emitting element) OLED which operates so as to emit light by the light emitting drive current generated by the pixel drive circuit DC being supplied to the pixel electrode 15.

In particular, the pixel drive circuit DC comprises the transistor (select transistor) Tr11 in which the gate terminal is connected to the select line Ls, the drain terminal is connected to the data line Ld and the source terminal is connected to the connection point N11, the transistor (drive transistor) Tr12 in which the gate terminal is connected to the connection point N11, the drain terminal is connected to the power voltage line Lv and the source terminal is connected to the connection point N12 and the capacitor Cs which is connected between the gate terminal and the source terminal of the transistor Tr12.

Here, the n-channel type field effect transistor (thin film transistor) is applied for both transistors Tr11 and Tr12. The transistors Tr11 and Tr12 may be the p-channel type, and the electrical relation of the source terminal and the drain terminal will be opposite in such case.

Further, the capacitor Cs is a capacitance component constituted with a parasitic capacitance formed between the gate terminal and the source terminal of the transistor Tr12 or a supportive capacitance additionally provided between the gate terminal and the source terminal of the transistor Tr12, or the capacitor Cs is a capacitance component constituted with both the parasitic capacitance and the supportive capacitance. When the transistor Tr12 is the p-channel type, one end of the capacitor Cs will be connected to the side of power voltage line Lv.

In the organic EL element OLED, the anode terminal (the pixel electrode 15 which becomes anode electrode) is connected to the connection point N12 of the above pixel drive circuit DC and the cathode terminal (cathode electrode) is integrally formed with the counter electrode 19 and is directly or indirectly connected to a predetermined standard voltage Vcom (for example, ground voltage Vgnd). Here, the counter electrode 19 is formed with a single electrode layer (solid electrode) so as to commonly oppose to the pixel electrode 15 of a plurality of display pixels PIX which are two-dimensionally arranged on the insulative substrate 11. Thereby, the above standard voltage Vcom is commonly applied to a plurality of display pixels PIX.

Here, the select line Ls shown in FIGS. 1 and 2 is connected to the select driver (omitted from drawing), and the select signal Ssel to set the plurality of display pixels PIX (color pixels PXr, PXg and PXb) which are arranged in the row direction of the display panel 10 be in a select state is applied to the select line Ls at a predetermined timing. Further, the data line Ld is connected to the data driver (omitted from drawing), and the tone signal Vpix according to the display data is applied to the data line Ld at a timing so as to synchronize with the select state of the above display pixels PIX. Here, the tone signal Vpix is a voltage signal to set the light emitting brightness tone of the organic EL element OLED.

Moreover, for example, the power voltage line Lv is directly or indirectly connected to a predetermined high potential power source, and a predetermined high voltage (power voltage Vdd) in which the potential is higher than the standard voltage Vcom applied to the counter electrode 19 of the organic EL element OLED to make the light emitting drive current according to the display data flow into the pixel electrode 15 of the organic EL electrode OLED provided in each of the display pixels PIX (color pixels PXr, PXg and PXb) is applied to the power voltage line Lv.

That is, in the pixel drive circuit DC shown in FIG. 2, the power voltage Vdd and the standard voltage Vcom are respectively applied to the ends (drain terminal of transistor Tr12 and cathode terminal of organic EL element OLED) of a pair of the transistor Tr12 and the organic EL element OLED which are serially connected in each of the display pixels PIX and a forward bias is given to the organic EL element OLED to make the organic EL element OLED be in a light emittable state. Further, the current value of the light emitting drive current which flows into the organic EL element OLED is controlled according to the tone signal Vpix.

In the drive control operation in the display pixel PIX having the above described circuit structure, first, the transistor Tr11 operates so as to be turned on to be set to the select state by applying the select signal Ssel of the select level (on level; for example, high level) to the select line Ls from the select driver during a predetermine period. By synchronizing to this timing, the tone signal Vpix having a voltage value according to the display data is controlled so as to be applied to the data line Ld from the data driver. Thereby, a potential according to the tone signal Vpix is applied to the connection point N11 (that is, gate terminal of the transistor Tr12) via the transistor Tr11.

In the pixel drive circuit DC having the circuit structure shown in FIG. 2, the current value of the current between the drain terminal and the source terminal of the transistor Tr12 (that is, light emitting drive current which flows into organic EL element OLED) is determined by the potential difference between the drain terminal and the source terminal and the potential difference between the gate terminal and the source terminal. Here, the power voltage Vdd which is applied to the drain terminal (drain electrode) of the transistor Tr12 and the standard voltage Vcom which is applied to the cathode terminal (cathode electrode) of the organic EL element OLED are fixed values. Therefore, the potential difference between the drain terminal and the source terminal of the transistor Tr12 is fixed in advance by the power voltage Vdd and the standard voltage Vcom. Then, the potential difference between the gate terminal and the source terminal of the transistor Tr12 is primarily determined by the potential of the tone signal Vpix. Therefore, the current value of the current which flows between the drain terminal and the source terminal of the transistor Tr12 can be controlled by the tone signal Vpix.

In such way, the transistor Tr12 operates so as to be turned on in the conductive state (that is, conductive state according to the tone signal Vpix) according to the potential of the connection point N11 and the light emitting drive current having a predetermined current value flows into the standard voltage Vcom (ground potential Vgnd) in the low potential side from the power voltage Vdd in the high potential side via the transistor Tr12 and the organic EL element OLED. Thereby, the organic EL element OLED operates so as to emit light at the brightness tone according to the tone signal Vpix (that is, display data). Further, at this time, load is accumulated (charged) in the capacitor Cs between the gate terminal and the source terminal of the transistor Tr12 based on the tone signal Vpix applied to the connection point N11.

Subsequently, in the non-select period after the above select period is finished, the transistor Tr11 of the display pixel PIX operates so as to be turned off and to be set in the non-select state by the select signal Ssel of the non-select level (off level; for example, low level) being applied to the select line Ls. Thereby, the data line Ld and the pixel drive circuit DC (in particular, connection point N11) are electrically cut off. At this time, the voltage corresponding to the tone signal Vpix is retained in the gate terminal of the transistor Tr12 (that is, potential difference between gate terminal and source terminal is retained) by the accumulated load being retained in the above capacitor Cs.

Therefore, similarly to the light emitting operation in the above described select state, a predetermined light emitting drive current flows into the organic EL element OLED from the power voltage Vdd via the transistor Tr12 to continue the light emitting operation state.

This light emitting operation state is controlled so as to be continued during 1 frame period, for example, until the next tone signal Vpix is applied (written). Further, the image display operation to display the desired image information can be executed by orderly executing the above described drive control operation for each column, for example, for all of the display pixels PIX (each color pixel PXr, PXg and PXb) which are two-dimensionally arranged in the display panel 10.

Here, in FIG. 2, a circuit structure which corresponds to the tone control system of a voltage assigned type which makes the organic EL element OLED operate so as to emit light at a desired brightness tone by controlling the current value of the light emitting drive current to be flown into the organic EL element OLED by adjusting (specifying) the voltage value of the tone signal Vpix to be written in each of the display pixels PIX (in particular, gate terminal of transistor Tr12 of pixel drive circuit DC; connection point N11) according to the display data is shown as the pixel drive circuit DC provided in the display pixel PIX. However, the pixel drive circuit DC may have a circuit structure of the tone control system of a current assigned type which makes the organic EL element OLED operate so as to emit light at a desired brightness tone by controlling the current value of the light emitting drive current to be flown into the organic EL element OLED by adjusting (specifying) the current value of the current to be supplied (to be written) to each of the display pixels PIX according to the display data.

Moreover, in the pixel drive circuit DC shown in FIG. 2, a circuit structure in which two n-channel type transistors Tr11 and Tr12 are used is shown. However, the display panel according to the present invention is not limited to this. A display panel may have other circuit structure in which three or more transistors are used. Further, a display panel which only uses the p-channel type transistor as the circuit element or a display panel which mixedly uses transistors having a channel property of n-channel type and a channel property of p-channel type may be applied. Here, as shown in FIG. 2, when only the n-channel type transistor is used as the pixel drive circuit DC, a transistor having a stable operation property can be easily manufactured by using the manufacturing technique of amorphous silicon semiconductor which is already established, and the pixel drive circuit in which the dispersion in the light emitting property of the display pixels is suppressed can be realized.

### <Device Structure of the Display Pixel>

Next, the particular device structure (plan layout and cross sectional structure) of the display pixel (pixel drive circuit and organic EL element) having the above described circuit structure will be described.

Here, a device structure in a case where the organic EL element having a top-emission type light emitting structure is applied will be described.

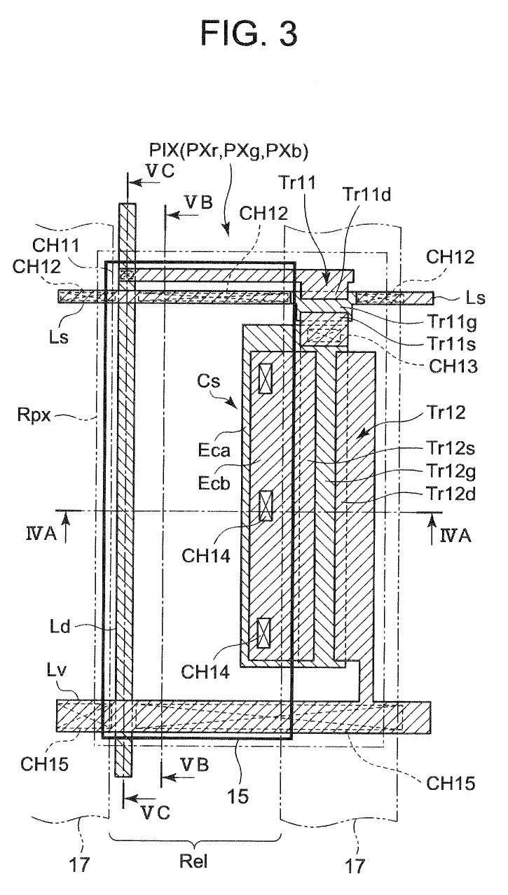

FIG. 3 is a diagram showing an example of a plan layout of the display pixel which is applicable in the display apparatus (display panel) according to the present invention.

Here, a plan layout of one specific color pixel among the color pixels PXr, PXg and PXb of red (R), green (G) and blue (B) of the display pixel PIX shown in FIG. 1 is shown.

Here, in FIG. 3, the layer in which each of the transistors and the wiring layers and the like of the pixel drive circuit DC are formed is mainly shown, and the hatchings are conveniently carried out in order to clearly show the dispositions and the planar shapes of each of the wiring layers and each of the electrodes.

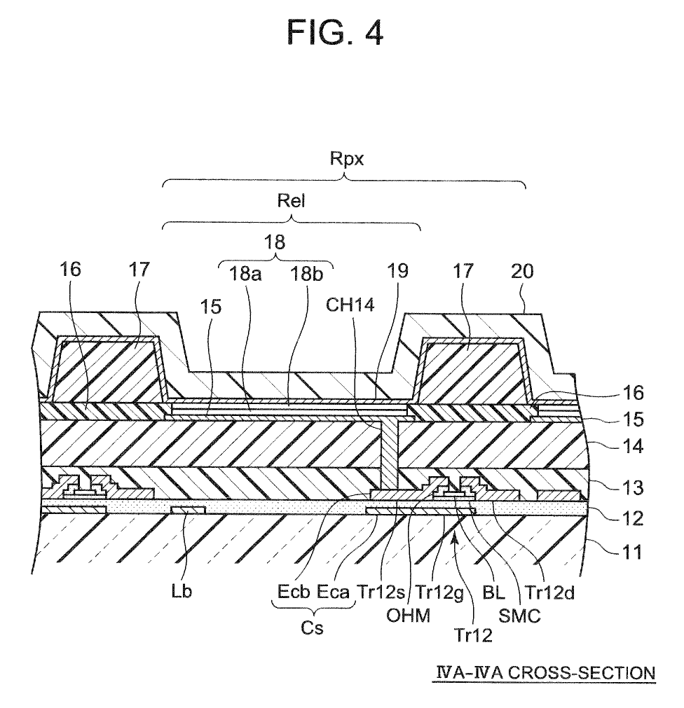

Further, FIG. 4 is a cross sectional diagram showing a cross section surface cut along the line IVA-IVA (in the specification, “IV” is conveniently used as a symbol corresponding to roman numeral “4” shown in FIG. 3) in the display pixel having a plan layout shown in FIG. 3.

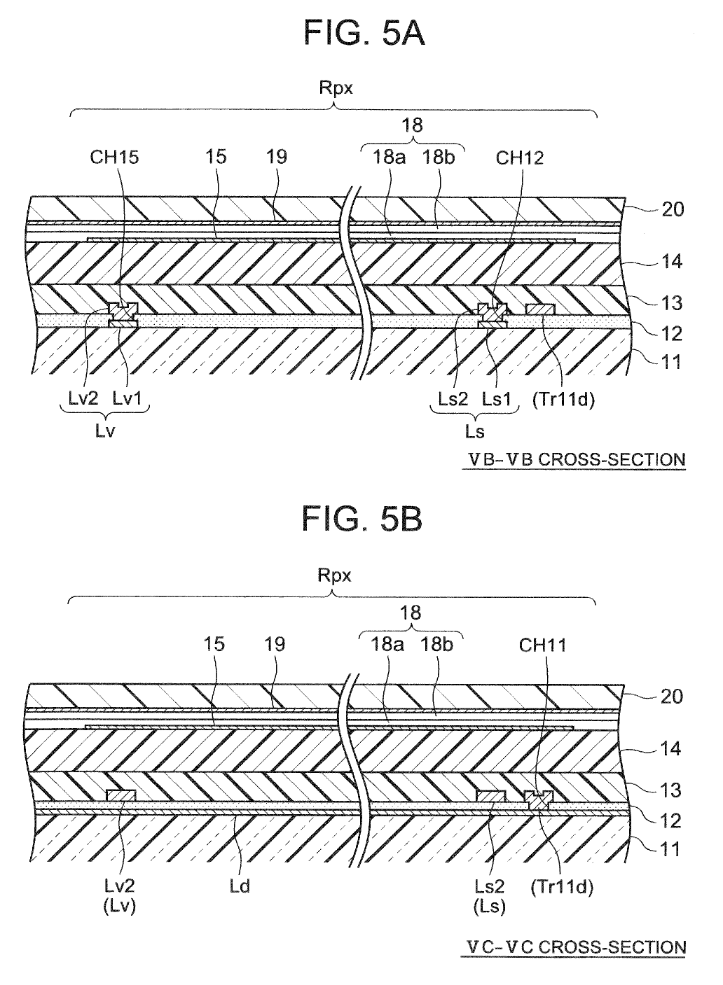

FIGS. 5A and 5B are cross sectional diagrams showing the cross section surfaces cut along the line VB-VB (in the specification, “V” is conveniently used as a symbol corresponding to roman numeral “5” shown in FIG. 3) and the line VC-VC in the display pixel having a plan layout shown in FIG. 3.

In particular, for example, in the display pixel (color pixel) PIX shown in FIG. 2, the select line Ls and the power voltage line Lv are respectively disposed so as to extend in the row direction (left-right direction in drawing) to the marginal region at the upper side and the lower side of the drawing in the pixel forming region Rpx which is set in one surface side of the insulative substrate 11 as shown in FIG. 3. Further, the data line Ld is disposed so as to extend in the column direction (top-down direction in drawing) to the marginal region at the right side of the drawing so that the data line Ld orthogonally crosses the lines Ls and Lv. Further, the bank 17 is disposed at the marginal region at the right side of the plan layout so as to extend in the column direction (top-down direction in drawing) across the display pixels (color pixels) which are adjacent to the right side.

Here, for example, the data line Ld is provided more in the lower layer side (insulative substrate 11 side) than the select line Ls and the power voltage line Lv as shown in FIGS. 3 to 5A and 5B, and the data line Ld is formed by the same process as the process to form the gate electrodes Tr11g and Tr12g by patterning the gate metal layer which is for forming the gate electrodes Tr11g and Tr12g of the transistors Tr11 and Tr12.

Further, the data line Ld is connected to the drain electrode Tr11d of the transistor Tr11 via the contact hole CH11 provided at the gate insulation film 12 which is formed so as to cover the data line Ld.

The select line Ls and the power voltage line Lv are provided more in the upper layer side than the data line Ld and the gate electrodes Tr11g and Tr12g. The select line Ls and the power voltage line Lv are formed by patterning the source/drain metal layer for forming the source electrodes Tr11s, Tr12s and the drain electrodes Tr11d, Tr12d of the transistors Tr11, Tr12 and are formed by the same process as the process to form the source electrodes Tr11s, Tr12s and the drain electrodes Tr11d, Tr12d.

Here, the contact hole CH15 is provided at the gate insulation film 12 excluding the region where the power voltage line Lv overlaps the data line Ld in a planar manner (in a plan view) in the column direction in which the power voltage line Lv is extended.

The select line Ls is connected to the gate electrode Tr11g via the contact holes CH12 which are provided at the gate insulation film 12 and which are positioned at both ends of the gate electrode Tr11g of the transistor Tr11. Further, the power voltage line Lv is integrally formed with the drain electrode Tr12d of the transistor Tr12.

Here, for example, as shown in FIGS. 5A and 5B, the select line Ls and the power voltage line Lv may have a wiring structure in which the lower layer wiring layers Ls1, Lv1 and the upper layer wiring layers Ls2, Lv2 are layered in order to reduce the resistance. For example, the lower layer wiring layers Ls1, Lv1 are same layer as the gate electrodes Tr11g, Tr12g of the transistors Tr11, Tr12, and are formed by a process which is the same as the process to form the gate electrodes Tr11g, Tr12g by patterning the gate metal layer which is for forming the gate electrodes Tr11g, Tr12g.

Further, both of the upper layer wiring layers Ls2, Lv2 are same layer as the source electrodes Tr11s, Tr12s and the drain electrodes Tr11d, Tr12d of the transistors Tr11, Tr12 as described above, and are formed by the process which is the same as the process to form the source electrodes Tr11s, Tr12s and the drain electrodes Tr11d, Tr12d by patterning the source/drain metal layer which is for forming the source electrodes Tr11s, Tr12s and the drain electrodes Tr11d, Tr12d.

Here, the lower layer wiring layers Ls1, Lv1 may be formed with aluminum alloy such as simple aluminum (Al), aluminum-titanium (AlTi), aluminum-neodymium-titanium (AlNdTi) or a single layer or an alloy layer of low resistance metal for reducing the wiring resistance such as copper (Cu), or may have a laminate structure in which the transition metal layer for reducing migration such as chromium (Cr), titanium (Ti) and the like is provided at the lower layer of the low resistant metal layer.

Further, the upper layer wiring layers Ls2, Lv2 may have a laminate structure of the transition metal layer for reducing the migration such as chromium (Cr), titanium (Ti) and the like and the low resistance metal layer for reducing the wiring resistance such as simple aluminum, aluminum allow or the like which is provided on the lower layer of the transition metal layer.

Further, more in particular, in the pixel drive circuit DC, the transistor Tr11 shown in FIG. 2 is disposed so as to extend along the row direction and the transistor Tr12 is disposed so as to extend along the column direction, for example, as shown in FIG. 3. Here, each of the transistors Tr11 and Tr12 has a well known thin film transistor structure of field effective type. That is, for example, each of the transistors Tr11 and Tr12 has a reversed stagger structure respectively comprising the gate electrode Tr11g, Tr12g formed on the substrate 11, the semiconductor layer SMC formed in the region corresponding to the gate electrode Tr11g, Tr12g via the gate insulation film 12 formed on the gate electrode Tr11g, Tr12g so as to cover them and the source electrode Tr11s, Tr12s and the drain electrode Tr11d, Tr12d formed so as to extend to both side portions of the channel of the semiconductor layer SMC.

On the channel of the semiconductor layer SMC in which the source electrode Tr11s, Tr12s and the drain electrode Tr11d and Tr12d of each of the transistors Tr11, Tr12 are respectively disposed at both end portions so as to oppose to one another, a channel protection layer (block layer) BL constituted with oxide silicon, nitride silicon or the like for preventing the etching damage to the semiconductor layer SMC occurring in the manufacturing process is formed. Further, on both end portions of the channel of the semiconductor layer SMC in which the source electrode Tr11s, Tr12s and the drain electrode Tr11d, Tr12d respectively contact, an impurity layer OHM for realizing the ohmic connection between the semiconductor layer SMC and the source electrode Tr11s, Tr12s and between the semiconductor layer SMC and the drain electrode Tr11d, Tr12d is formed.

Moreover, so as to correspond to the circuit structure of the pixel drive circuit DC shown in FIG. 2, in the transistor Tr11, the gate electrode Tr11g is connected to the select line Ls via the contact hole CH12 provided at the gate insulation film 12 as shown in FIG. 3. Further, the drain electrode Tr11d is connected to the data line Ld via the contact hole CH11 provided at the gate insulation film 12.

In the transistor Tr12, the gate electrode Tr12g is connected to the source electrode Tr11s of the transistor Tr11 via the contact hole CH13 provided at the gate insulation film 12 as shown in FIGS. 3 and 4. Further, the drain electrode Tr12d is integrally formed with the power voltage line Lv. The source electrode Tr12s is connected to the pixel electrode 15 of the organic EL element OLED via the contact hole CH14 provided at the protection insulation film 13 and the flattening film 14.

Moreover, in the capacitor Cs, the electrode Eca integrally formed with the gate electrode Tr12g of the transistor Tr12 on the insulative substrate 11 and the electrode Ecb integrally formed with the source electrode Tr12s of the transistor Tr12 on the gate insulation film 12 are provided so as to oppose to one another by having the gate insulation film 12 in between as shown in FIGS. 3 and 4B.

Further, as described above, the contact hole CH14 is provided at the protection insulation film 13 and the flattening film 14 above the electrode Ecb, and the electrode Ecb is connected to the pixel electrode 15 of the organic EL element OLED via the contact hole CH14.

As shown in FIGS. 3 to 5A and 5B, the organic EL element OLED is provided on the upper surface of the protection insulation film 13 and the flattening film 14 which are formed so as to cover the transistors Tr11, Tr12. Further, the organic EL element OLED is formed by orderly layering the pixel electrode (for example, anode electrode) 15, the organic EL layer (light emitting function layer) 18 and the counter electrode (for example, cathode electrode) 19.

The pixel electrode 15 is formed of a material having the light reflection characteristic, and is connected to the source electrode Tr12s of the transistor Tr12 via the contact hole CH14 which is provided by penetrating the protection insulation film 13 and the flattening film 14 and a predetermined light emitting drive current is supplied.

The organic EL layer 18 is constituted of the inter-layer insulation film 16 formed in the region (bordering region) between the pixel electrodes 15 of the adjacent display pixels PIX which is on the flattening film 14 and the hole transporting layer 18a and the electron transporting light emitting layer 18b, for example, which are formed in the EL element forming region Rel defined (a region enclosed by bank 17) by the bank 17 disposed on the inter-layer insulating film 16 so as to continuously protrude.

The counter electrode 19 is formed of a single electrode layer (solid electrode) of a material having the light transparency characteristic, and is provided so as to commonly oppose to the pixel electrode 15 of each of the display pixels PIX which are two dimensionally arranged on the insulative substrate 11.

Here, the counter electrode 19 is provided so as to extend on the bank 17 which defines the EL element forming region Rel and not only each EL element forming region Rel.

Further, the bank 17 is formed at the bordering region of EL element forming region Rel of display pixels (color pixel) which are adjacent in the left-right direction of the planar layout shown in FIG. 3 at the periphery of the EL element forming region Rel. Further, a portion of select line Ls and power voltage line Lv and the transistors Tr11, Tr12 planarly (in a plan view) overlaps with the bank 17. Therefore, the bank 17 moderates the influence of the parasitic capacitance by the above counter electrode 19 formed on the bank 17. Here, the data line Ld may be disposed at lower side of the bank 17 for the similar purpose.

Moreover, in the panel structure shown in FIGS. 3 to 5A and 5B, the select line Ls and the power voltage line Lv have a laminate wiring structure, and the upper layer wiring layers Ls2, Lv2 are formed by patterning the source/drain metal layer which is for forming the source electrodes Tr11s, Tr12s and the drain electrodes Tr11d, Tr12d of the transistors Tr11, Tr12, respectively. Further, the select line Ls is connected to the gate electrode Tr11g of the transistor Tr11 via the contact hole CH12, and the power voltage line Lv is integrally formed with the drain electrode Tr12d of the transistor Tr12. Furthermore, the data line Ld is formed by patterning the gate metal layer which is for forming the gate electrodes Tr11g, Tr12g of the transistors Tr11, Tr12, respectively, and the data line Ld is connected to the drain electrode Tr11d of the transistor Tr11 via the contact hole CH11.

Here, the contact hole CH12 is provided except for the region in which the gate electrode Tr11g of the transistor Tr11 is provided and the region in which the data line Ld is provided in the extending direction of the select line Ls. Therefore, as shown in FIGS. 5A and 5B, the select line Ls is constituted of the lower layer wiring layer Ls1 and the upper layer wiring layer Ls2 in the region where the contact hole CH12 exists, is constituted of only the upper layer wiring layer Ls2 in the region where overlaps with the data line Ld, is not formed in the region where the gate electrode Tr11g is provided, and is connected to both ends of the gate electrode Tr11g of the transistor Tr11.

Further, the contact hole CH15 is provided except for the region in which the data line Ld is provided in the extending direction of the power voltage line Lv.

Therefore, as shown in FIGS. 5A and 5B, the power voltage line Lv is constituted of the lower layer wiring layer Lv1 and the upper layer wiring layer Lv2 in the region where the contact hole CH15 exists and is constituted of only the upper layer wiring layer Lv2 in the region where overlaps the data line Ld.

Here, the wiring structure of the select line Ls and the power voltage line Lv is not necessarily limited to the above structure. For example, the select line Ls may be integrally provided with the gate electrode Tr11g and the data line Ld may be integrally provided with the drain electrode Tr11d without having the contact holes CH11 and CH12 provided by forming the select line Ls at the lower layer of the gate insulation film 12 by patterning the gate metal layer and by forming the data line Ld at the upper layer of the gate insulation film 12 by patterning the source/drain metal layer.

Moreover, as for the structure to electrically connect the pixel electrode 15 and the source electrode Tr12s of the transistor Tr12 of the pixel drive circuit DC (or electrode Ecb in the other side of capacitor Cs), the pixel electrode 15 may be directly connected with the source electrode Tr12s by embedding the electrode material which forms the pixel electrode 15 in the contact hole CH14 which is provided so as to penetrate the protection insulation film 13 and the flattening film 14 as shown in FIG. 4.

Further, the pixel electrode 15 and the source electrode Tr12s may be connected via a contact metal by embedding the contact metal (omitted from drawing) formed of a conductive material which is different from the pixel electrode 15 in the contact hole CH14.

The bank 17 is disposed at the bordering region (particularly, at the region between each pixel electrode 15) of a plurality of display pixels (color pixels) which are two-dimensionally arranged in the display panel 10 in the column direction (so as to have a planar pattern in like a fence shape enclosing a plurality of pixel electrodes 15 as shown in FIG. 1 in an entire display panel 10 or in a lattice shape enclosing each pixel electrode 15) of the display panel 10.

Here, as shown in FIGS. 3 and 4, the transistor Tr12 is formed in the column direction of the display panel 10 (insulative substrate 11) within the bordering region so as to extend, and the bank 17 approximately covers the transistor Tr12 and is formed on the inter-layer insulation film 16 formed between the pixel electrode 15 of each pixel forming region Rpx so as to continuously protrude in the height direction from the surface of the insulative substrate 11, for example. Thereby, the region enclosed by the bank 17, that is, the region including the pixel electrode 15 of a plurality of display pixels PIX arranged in the column direction (top-down direction in FIG. 1) is defined as the applying region (that is, EL element forming region Rel) of the solution or the solvent of suspension liquid including organic compound material (organic compound containing solution) at the time of forming the organic EL layer 18 (for example, hole transporting layer 18a and electron transporting light emitting layer 18b) in the after-mentioned manufacturing method.

Moreover, the bank 17 is formed by using a photosensitive resin material, for example, and a surface treatment to make at least the surface of the bank 17 (sides and upper surface) have repellency characteristic to the organic compound containing solution which is applied to the EL element forming region Rel is carried out at the time of forming the organic EL layer 18.

Further, at the entire region of one surface side of the insulative substrate 11 in which the pixel drive circuit DC, the organic EL element OLED and the bank 17 are formed, the sealing layer 20 having a function as a protection insulation film (passivation film) is formed so as the cover the entire region of one surface side of the insulative substrate 11 as shown in FIGS. 4, 5A and 5B, for example. Furthermore, a sealing substrate constituted of a glass substrate or the like (omitted from drawing) may be joined so as to opposed to the insulative substrate 11.

Moreover, in the display panel according to the embodiment, particularly, the film thickness of the hole transporting layer 18a among the organic EL layer 18 formed on the pixel electrodes 15 of the EL element forming region Rel is formed so as to be in a different particular film thicknesses for each of the color pixels PXr, PXg and PXb of R, G and B.

In particular, as the organic EL layer (light emitting function Layer) 18, the film thickness of the hole transporting layer 18a is set to approximately 15 nm±10 nm for the color pixel PXr having the luminescent color of red (R), the film thickness of the hole transporting layer 18a is set to approximately 95 nm±20 nm for the color pixel PXg having the luminescent color of green (G), and the film thickness of the hole transporting layer 18a is set to approximately 90 nm±20 nm for the color pixel PXb having the luminescent color of blue (B) when the inter-layer is formed in a film thickness of 10 nm and when the electron transporting light emitting layer 18b is formed in a film thickness of 70 nm as the layer structure common to each of the color pixels PXr, PXg and PXb in the layer structure in which the inter-layer is inserted between the hole transporting layer 18a and the electron transporting light emitting layer 18b in addition to the above described hole transporting layer 18a and the electron transporting light emitting layer 18b.

In such display panel 10 (display pixel PIX), the light emitting drive current having a predetermined current value flows between the source terminal and the drain terminal of the transistor Tr12 based on the tone signal Vpix according to the display data supplied via the data line Ld to be supplied to the pixel electrode 15 of the organic EL element OLED. Thereby, the organic EL element OLED of each display pixel (color pixel) PIX operates so as to emit light in a desired brightness tone according to the display data.

Here, in the display panel 10 according to the embodiment, the top emission type light emitting structure in which the light emitted at the organic EL layer 18 of each display pixel PIX is directly emitted in the visual field side (upper portion of FIGS. 4, 5A and 5B) via the counter electrode 19 having the light transparency characteristic and is reflected by the pixel electrode 15 having the light reflecting characteristic to be emitted in the visual field side via the counter electrode 19 can be realized by the pixel electrode 15 having the light reflecting characteristic (high reflection factor with respect to visible light) and by the counter electrode 19 having a light transparency characteristic (high transmittance with respect to visible light).

In the light emitting structure, the light emitted in the electron transporting light emitting layer 18b is emitted directly in the visual field side via the counter electrode 19 and is also reflected at the surface of the pixel electrode 15 having the light reflecting characteristic via the inter-layer and the hole transporting layer 18a having a specific film thickness, and again, the light is emitted in the visual field side via the hole transporting layer 18a, the inter-layer, the electron transporting light emitting layer 18b and the counter electrode 19. At this time, as described above, by setting the film thickness of the organic EL layer 18 (hole transporting layer 18a) formed at the EL element forming regions Rel of each of the color pixels PXr, PXg and PXb of R, G and B so as to be different specific film thicknesses corresponding to each color of R, G and B, the chromaticity and the emission intensity can be adjusted by using the interference effect of the light of the light emitted in the electron transporting light emitting layer 18b is directly emitted in the visual field side and the light which is reflected at the surface of the pixel electrode 15 having the light reflecting characteristic and which is emitted in the visual field side. Further, the shifting of chromaticity and the dispersion of brightness can be suppressed, and a good display property without running, blurring and the like of the image can be realized.

Moreover, in the display panel 10 according to the embodiment, the display panel has the top emission type light emitting structure. Therefore, each circuit element and wiring layer of the pixel drive circuit DC formed on the insulative substrate 11 can be disposed so as to planarly overlap with the organic EL element OLED formed on the protection insulation film 13 and the flattening film 14, and the power consumption may be tempted to be reduced and the life span of the panel can be tempted to be made longer by increasing the pixel opening ratio and also the degree of freedom of the layout design of the pixel circuit can be increased.

### <Manufacturing Method of the Display Panel>

Next, the manufacturing method of the display panel according to the embodiment will be described.

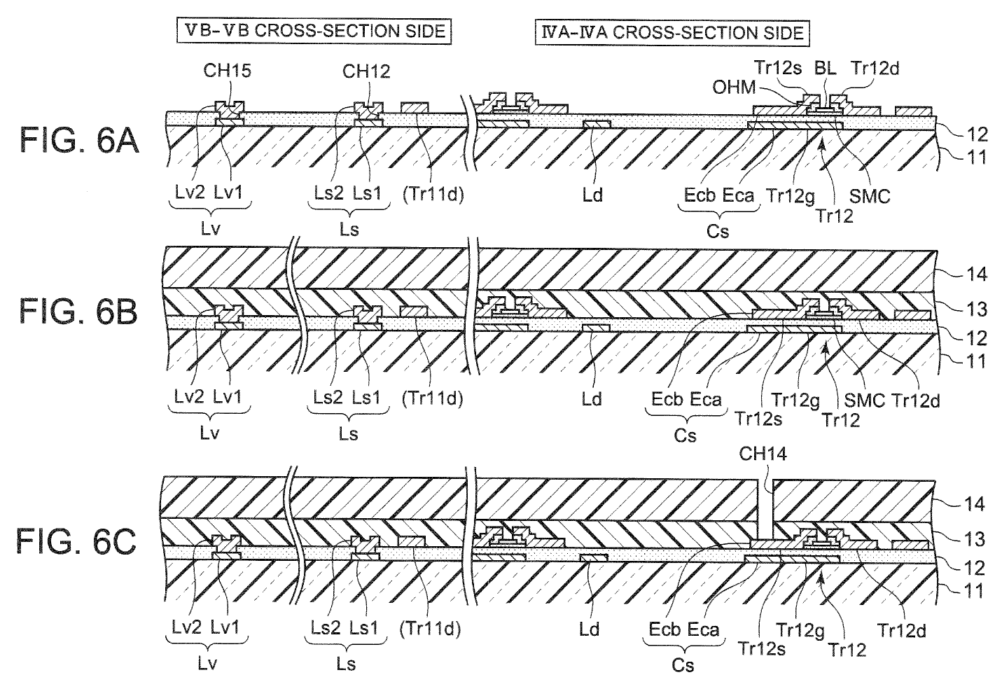

FIGS. 6A, 6B and 6C to 10 are process sectional diagrams showing an example of the manufacturing method of the display apparatus (display panel) according to the embodiment.

Here, a structure in which each portion (transistor Tr12, capacitor Cs, organic EL element OLED, select line Ls, power voltage line Lv and the like) among the cross sectional structure of the display panel cut along the line IVA-IVA and the line VB-VB shown in FIGS. 4 and 5A are conveniently extracted is shown, and the outline of the manufacturing method of the above described display panel will be described.

First, in the manufacturing method of the above described display panel, the wiring layer of the transistors Tr11, Tr12, the capacitor Cs, the data line Ld, the select line Ls, the power voltage line Lv and the like of the pixel drive circuit DC is formed (see FIGS. 3 to 5A and 5B) at the pixel forming region Rpx of the display pixel (color pixel) PIX which is set at one surface side (upper surface side of drawing) of the insulative substrate 11 of glass substrate and the like as shown in FIG. 6A.

In particular, the gate electrodes Tr11g, Tr12g, the electrode Eca in one side of the capacitor Cs which is integrally formed with the gate electrode Tr12g, the data line, the lower layer wiring layer Ls1 of the select line Ls and the lower layer wiring layer Lv1 of the power voltage line Lv are simultaneously formed on the insulative substrate 11 by patterning the same gate metal layer. Thereafter, the gate insulation film 12 is formed so as to cover the entire region of the insulative substrate 11.

Here, as shown in FIG. 3, the lower layer wiring layer Ls1 of the select line Ls and the lower layer wiring layer Lv1 of the power voltage line Lv are not formed at the region where the data line Ld intercepts with the select line Ls and at the region where the data line Ld intercepts with the power voltage line Lv so that they will not be electrically connected (insulated) to one another.

Subsequently, the contact hole CH11 is formed at a predetermined region of the gate insulation film 12 on the data line Ld. Further, the contact hole CH12 is formed at the gate insulation film 12 on the lower layer wiring layer Ls1 of the select line Ls. The contact hole CH15 is formed at the gate insulation film 12 on the lower layer wiring layer Lv1 of the power voltage line Lv. The contact hole CH13 is formed at a predetermined region of the gate insulation film 12 on the gate electrode Tr12g of the transistor Tr12.

Next, at the region corresponding to each of the gate electrodes Tr11g, Tr12g on the gate insulation film 12, for example, the semiconductor layer SMC formed of amorphous silicon, polysilicon or the like and the channel protection layer BL formed of silicon nitride or the like are formed. Further, the source electrodes Tr11s, Tr12s and the drain electrode Tr11d, Tr12d are respectively formed at the ends of the semiconductor layer SMC (channel) via the impurity layer OHM which is for ohmic connection.

Here, as shown in FIGS. 2 and 3, the drain electrode Tr11d of the transistor Tr11 is connected to the data line Ld via the contact hole CH11 formed at the gate insulation film 12. Further, the source electrode Tr11s is connected to the gate electrode Tr12g of the transistor Tr12 via the contact hole CH13 formed at the gate insulation film 12.

Further, at this time, the electrode Ecb in the other side of the capacitor Cs connected to the source electrode Tr12s, the upper layer wiring layer Ls2 of the select line Ls and the upper layer wiring layer Lv2 of the power voltage line Lv are simultaneously formed by patterning the same source/drain metal layer.

Here, the upper layer wiring layer Ls2 of the select line Ls is formed at the lower layer wiring layer Ls1 of the select line Ls so as to be electrically connected via the groove-like contact hole (opening) CH12 formed at the gate insulation film 12. Further, the upper layer wiring layer Lv2 of the power voltage line Lv is formed at the lower layer wiring layer Lv1 of the power voltage line Lv so as to be electrically connected via the groove-like contact hole (opening) CH15 formed at the gate insulation film 12. Thereby, the select line Ls having a laminate wiring structure constituted of the upper layer wiring layer Ls2 and the lower layer wiring layer Ls1 and the power voltage line Lv having a laminate wiring structure constituted of the upper layer wiring layer Lv2 and the lower layer wiring layer Lv1 are formed.

Here, the above mentioned source electrodes Tr11s, Tr12s and the drain electrodes Tr11d, Tr12d of the transistors Tr11, Tr12, respectively, the electrode Ecb in the other side of the capacitor Cs, the upper layer wiring layer Ls2 of the select line Ls, the upper layer wiring layer Lv2 of the power voltage line Lv may have a laminate wiring structure constituted of an aluminum alloy layer of aluminum-titanium (AlTi), aluminum-neodymium-titanium (AlNdTi) or the like and a transition metal layer of chromium (Cr) or the like for the purpose of reducing wiring resistance and reducing migration.

Next, as shown in FIG. 6B, the protection insulation film 13 formed of silicon nitride (SiN) is formed so as to cover the entire region of one surface side of the insulative substrate 11 including the transistors Tr11, Tr12, the capacitor Cs, the upper layer wiring layer Ls2 of the select line Ls and the upper layer wiring layer Lv2 of the power voltage line Lv, and the flattening film 14 is formed so as to be layered thereabove. Here, the film material used for the flattening film 14 and the thickness of the flattening film 14 are arbitrarily set so as to improve the flatness of the surface of the flattening film 14 the flattening film 14 by alleviating the surface bumps of the transistors Tr11, Tr12 and each wiring layer of the pixel drive circuit DC formed on the insulative substrate 11. In particularly, an organic material having a heat-curing characteristic (for example, acrylic resin, epoxy resin, polyimide resin or the like) can be preferably applied as the flattening film material which can be applied in the embodiment.

Next, as shown in FIG. 6C, the contact hole CH14 from which at least the upper surface of the source electrode Tr12s of the transistor Tr12 (or electrode Ecb in the other side of capacitor Cs) is exposed is formed by etching the flattening film 14 and the protection insulation film 13 by using the photolithographic method.

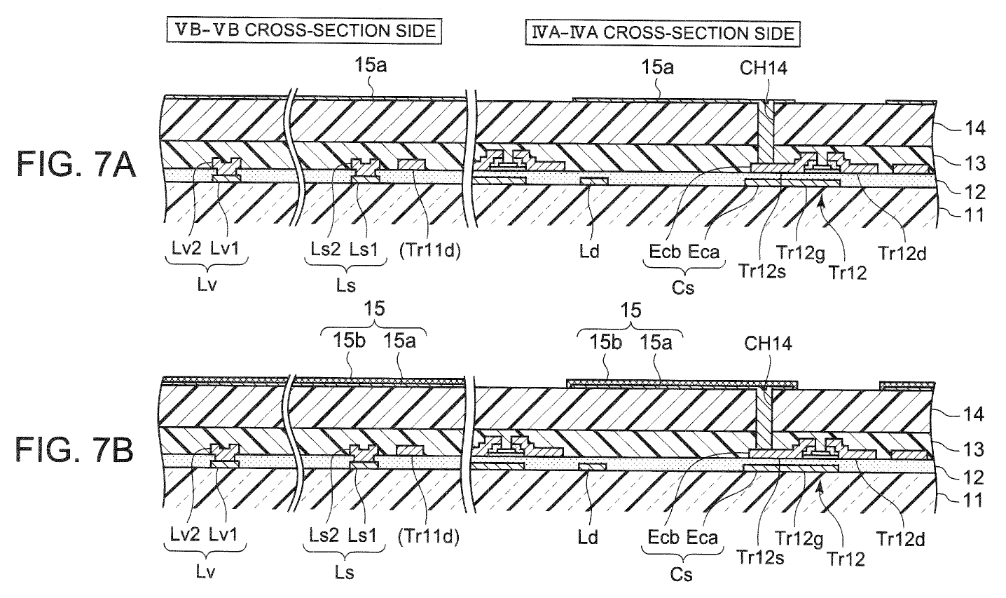

Next, a metallic thin film having a light reflecting characteristic (more particularly, having a high reflectance ratio with respect to the visual light range) formed of a metallic material such as silver (Ag), aluminum (Al) or the like or an alloy material such as aluminum-neodymium-titanium (AlNdTi) is formed on the flattening film 14 including the contact hole CH14 by using the spattering method or the like. Thereafter, as shown in FIG. 7A, the reflection layer 15a which electrically connects with the source electrode Tr12s of the transistor Tr12 in the contact hole CH14 and which extends onto the flattening film 14 by having a planar shape corresponding to the EL element forming region Rel in each display pixel PIX is formed by patterning the metallic thin film.

Next, the conductive oxidized metal layer formed of a transparent electrode material (having light transparency characteristic) such as a tin doped indium oxide (Indium Tin Oxide; ITO), a zinc doped indium oxide (Indium Zinc Oxide; IZO), a tungsten doped indium oxide (Indium Tungsten Oxide; IWO), a tungsten-zinc doped indium oxygen (Indium tungsten Zinc Oxide; IWZO) or the like is formed on the flattening film 14 including the reflection layer 15a by using the spattering method or the like. Thereafter, the transparent electrode layer 15b having a planar shape corresponding to each EL element forming region Rel and which covers at least the upper surface and end surfaces (side surfaces) of the reflection layer 15a is formed as shown in FIG. 7B by patterning the conductive oxidized metal layer.

Thereby, the pixel electrode 15 having the laminated electrode structure which has reflection layer 15a and the transparent electrode layer 15b and which is electrically connected to the source electrode Tr12s of the transistor Tr12 via the contact hole CH14 is formed.

In this forming process of the pixel electrode 15, the patterning of the transparent electrode layer 15b is carried out by etching the conductive oxidized metallic layer in a state where the upper surface and the sides of the reflection layer 15a formed in each EL element forming region Rel are completely covered. Therefore, the battery reaction between the conductive oxidized metallic layer (ITO or the like) and the reflection layer 15a can be prevented from occurring, and the reflection layer 15a can be prevented from being overly etched and can be prevented from receiving etching damage.

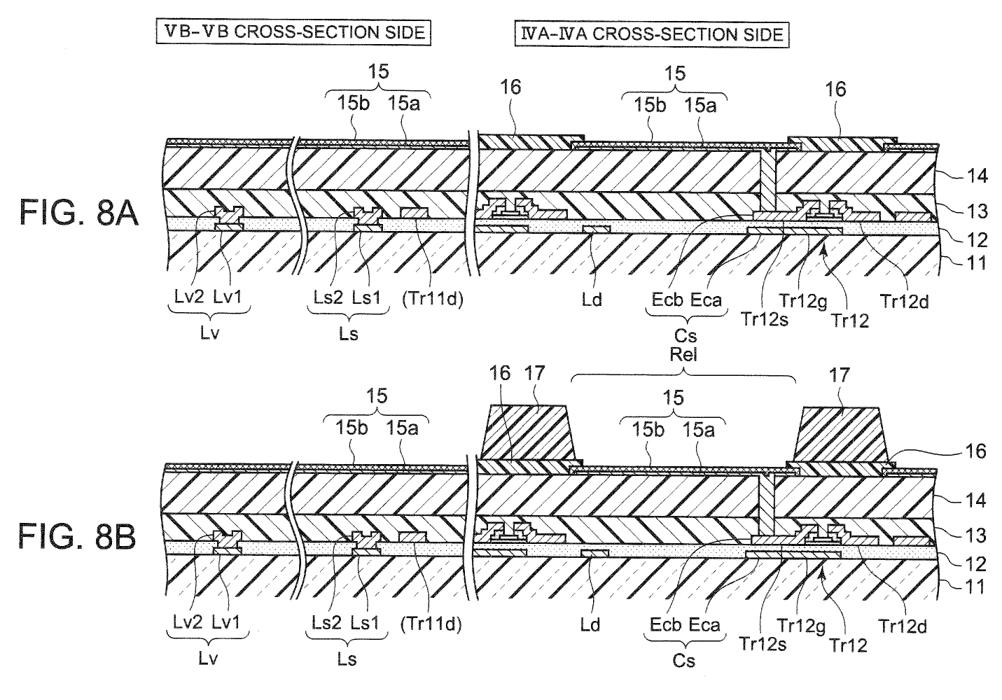

Subsequently, the inter-layer insulation film 16 shown in FIGS. 4 and 8A which covers the bordering region (that is, region between adjacent pixel electrodes 15) between adjacent display pixels (color pixels) PIX and which has an opening from which the upper surface of the pixel electrode 15 is exposed at each pixel forming region Rpx is formed by forming the insulation layer formed of a non-organic insulative material such as an oxide silicon film, a nitride silicon film or the like, for example, on the flattening film 14 including the pixel electrode 15 by using a chemical vapor deposition method (CVD method) or the like and carrying out patterning thereafter.

Next, as shown in FIG. 8B, the bank 17 formed of a photosensitive resin material such as polyimide, acrylic or the like is formed on the inter-layer insulation film 16 formed at the bordering region between adjacent display pixels PIX (pixel electrodes 15). In particular, the bank (partition wall) 17 which has a planar form of like a fence shape including a region which extends in the column direction of the display panel 10 which is the bordering region between the display pixels PIX which are adjacent in the row direction and which is continuously protruded in the height direction as shown in FIG. 1 is formed by pattering the photosensitive resin layer formed so as to cover the entire region of one surface side of the insulative substrate 11 including the inter-layer insulation film 16 and the pixel electrodes 15. In such way, the EL element forming region Rel of a plurality of display pixels (color pixels) PIX of same color which are arranged in the column direction of the display panel 10 is defined by being enclosed by the bank 17 and the inter-layer insulation film 16, and the upper surface of the pixel electrode 15 of each display pixel PIX is exposed at the EL element forming region Rel.

Next, after the insulative substrate 11 is cleansed with pure water, the treatment to make the surface of each pixel electrode 15 which is exposed at the EL element forming region Rel have a lyophilic characteristic to the after-mentioned organic compound containing solution of the hole transporting material or the electron transporting light emitting material is carried out by carrying out the oxygen plasma treatment, the UV ozone treatment or the like, for example. Subsequently, a treatment to make the surface of the bank 17 have repellency characteristic to the organic compound containing solution is carried out by carrying out the CF₄ plasma treatment to the surface of the bank 17. Here, when fluorine atom is included in the resin material itself which forms the bank 17 in advance, the above described repellency treatment does not necessarily need to be carried out.

In such way, a state where the repellency treatment is carried out only to the surface of the bank 17 and the surface of the pixel electrode 15 exposed at each pixel forming region Rpx which is defined by the bank 17 is not made to have repellency characteristic (lyophylic characteristic) is retained on the same insulative substrate 11. Therefore, even when the organic EL layer 18 (electron transporting light emitting layer 18b) is formed by applying the organic compound containing solution, the leakage and crossing over of the organic compound containing solution to the adjacent EL element forming regions Rel can be prevented and coloring of red (R), green (G) and blue (B) can be carried out distinctively by suppressing the color mixing of the adjacent pixels.

Here, “repellency characteristic” used in the embodiment is defined as a condition in which the contact angle is 50 degrees or greater when the after mentioned organic compound containing solution including the hole transporting material which becomes hole transporting layer 18a and organic compound containing solution including the electron transporting light emitting material which becomes the electron transporting light emitting layer 18b, or an organic solvent used for these solutions is dropped on the substrate or the like and the contact angle is measured. Further, “lyophilic characteristic” oppose to “repellency characteristic” is defined as a condition in which the contact angle is 40 degrees or smaller, preferably 10 degrees or smaller, in the embodiment.

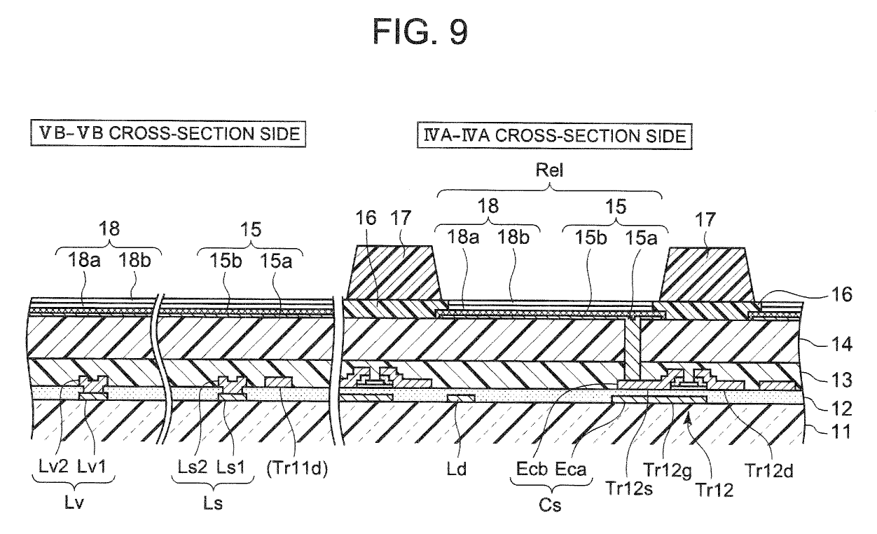

Next, solution or dispersion liquid of the hole transporting material formed of high polymer organic material is applied to the EL element forming region Rel of each color enclosed (defined) by the bank 17 by using the ink jet method, the nozzle printing method or the like which has good process control property and productivity. Thereafter, the hole transporting layer 18a is formed so as to have different specific film thickness for each color pixel PXr, PXg and PXb of colors R, G and B by heat-drying. Subsequently, the solution or dispersion liquid of the electron transporting light emitting material formed of a high polymer organic material corresponding to the luminescent color of R, G and B is applied on the hole transporting layer 18a for each color pixel PXr, PXg and PXb. Thereafter, the electron transporting light emitting layer 18b is formed by heat-drying. In such way, as shown in FIG. 9, the organic EL layer 18 having at least the hole transporting layer 18a and the electron transporting light emitting layer 18b formed so as to be laminated is formed on the pixel electrode 15. Here, the film forming process of the organic EL layer 18 will be described afterwards in detail.

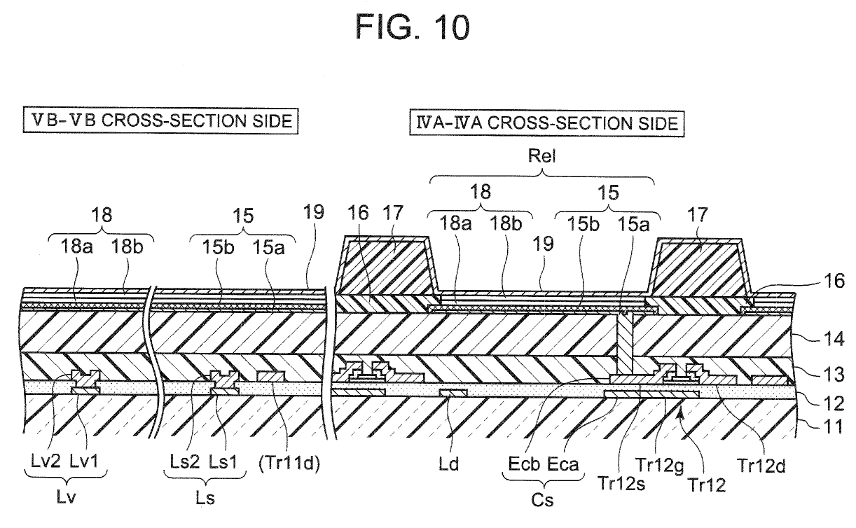

Thereafter, as shown in FIG. 10, the conductive layer (transparent electrode layer) having a light transparency characteristic is formed on the insulative substrate 11 including at least the EL element forming region Rel of each display pixel PIX, and the common counter electrode (for example, cathode electrode) 19 which opposes the pixel electrode 15 of each display pixel PIX by having the organic EL layer 18 (hole transporting layer 18a and electron transporting light emitting layer 18b) in between is formed.

In particular, a film structure which is transparent in the thickness direction in which the transparent electrode layer such as ITO or the like can be formed so as to be laminated by the spattering method on a thin film of metallic material after the thin film formed of a metallic material such as barium, magnesium, lithium or the like which becomes the electron injection layer is formed by the vapor deposition method or the like, for example, can be applied to the counter electrode 19. Here, the counter electrode 19 is formed as a single conductive layer (solid electrode) which also extends onto the bank 17 which defines each EL element forming region Rel and not only to the region which opposes the pixel electrode 15.

Next, after the above counter electrode 19 is formed, the sealing layer 20 formed of a silicon oxide film, a silicon nitride film or the like in formed at the entire region of one surface side of the insulative substrate 11 as the protection insulation film (passivation film) by the CVD method or the like. Thereby, the display panel 10 having the cross-sectional structure as shown in FIGS. 4, 5A and 5B is completed. Here, although is it omitted from the drawing, a sealing lid or a sealing substrate constituted of a glass substrate or the like may be attached so as to oppose to the insulative substrate 11 in addition to the panel structure as shown in FIGS. 4, 5A and 5B.

### <Film Forming Process and Manufacturing Apparatus of the Light Emitting Function Layer>

Next, the film forming process of the organic EL layer 18 (light emitting function layer) and the manufacturing apparatus for carrying out the film forming process in the manufacturing method of the above described display panel will be described in detail.

### (The First Configuration of the Film Forming Process and the Manufacturing Apparatus)

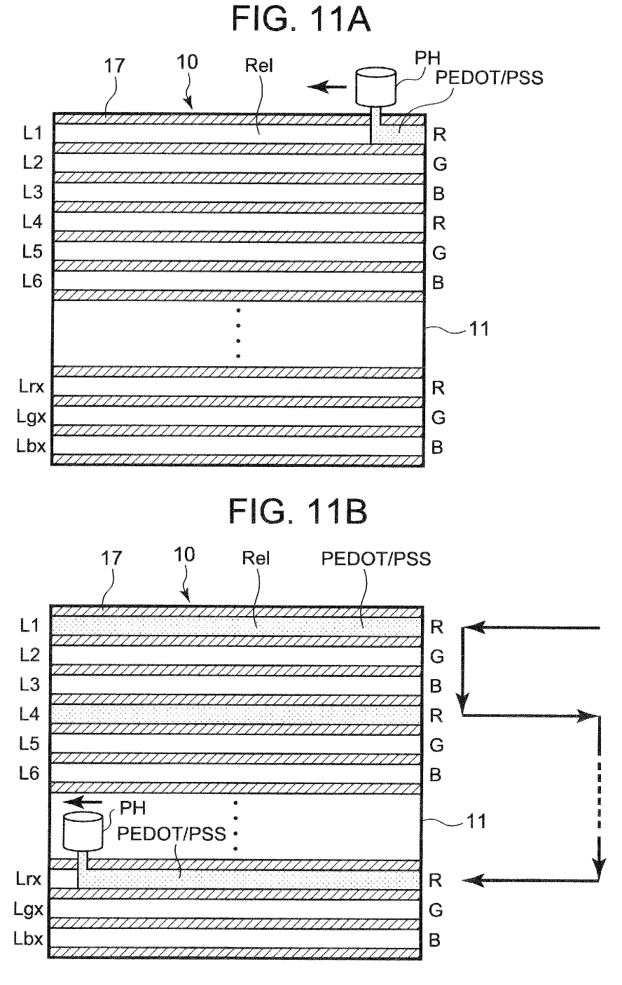

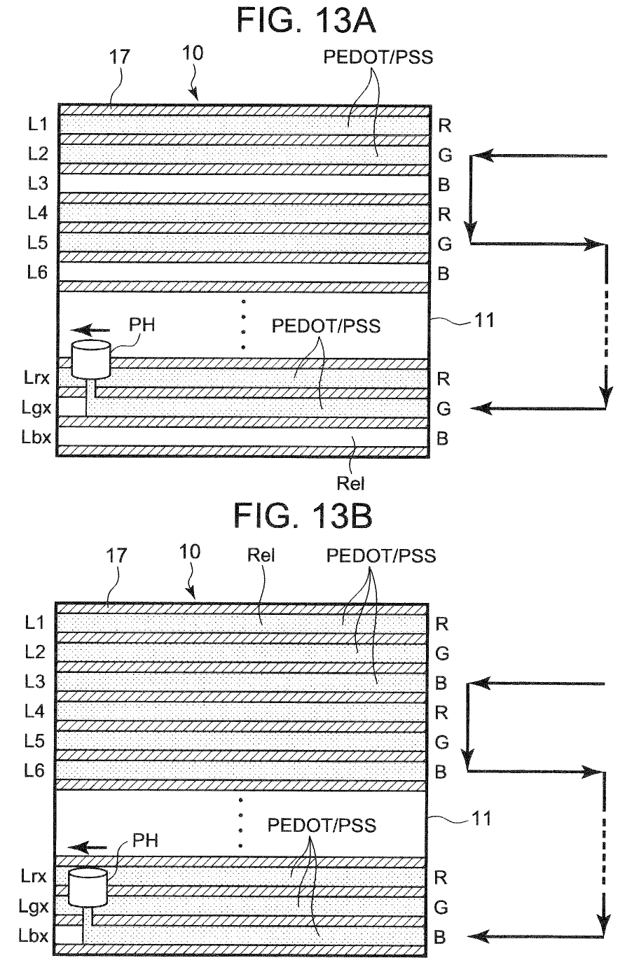

FIGS. 11A and 11B and FIGS. 13A and 13B are diagrams for explaining the film forming process of the hole transporting layer by the first configuration of the film forming process and the manufacturing apparatus in the manufacturing method of the display apparatus (display panel) according to the embodiment.

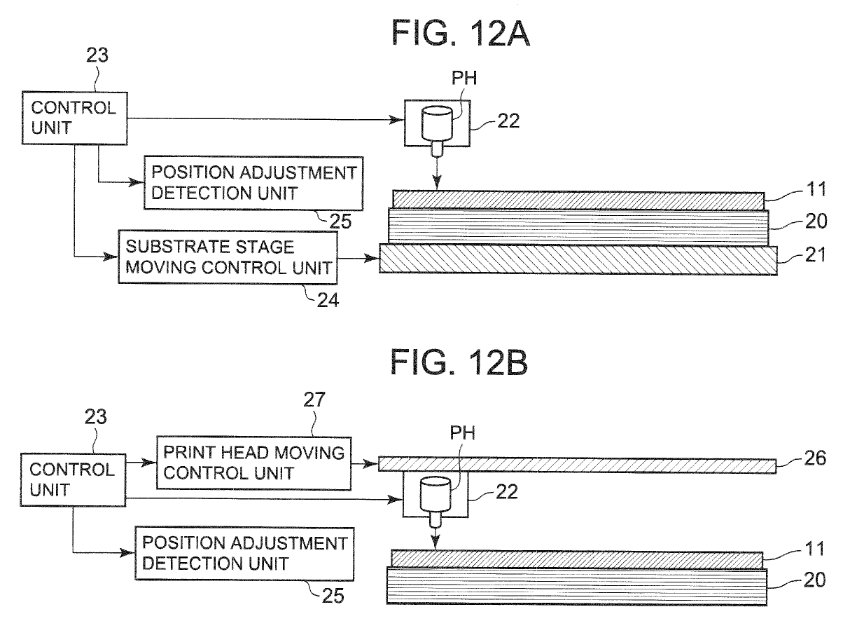

FIGS. 12A and 12B are diagrams showing an example of a structure of the manufacturing apparatus for carrying out the first configuration of the manufacturing method of the display apparatus according to the embodiment.

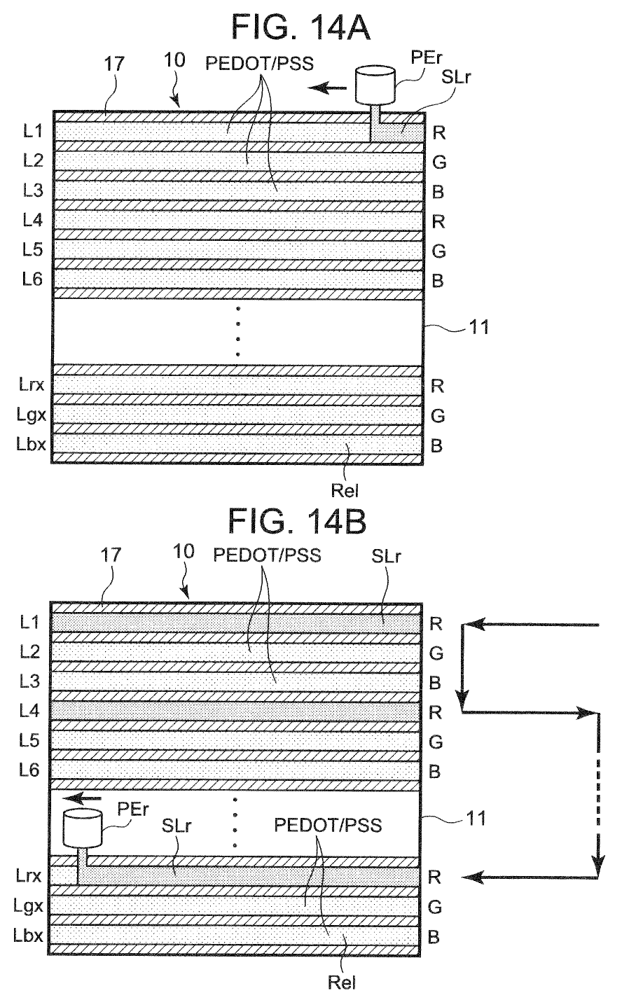

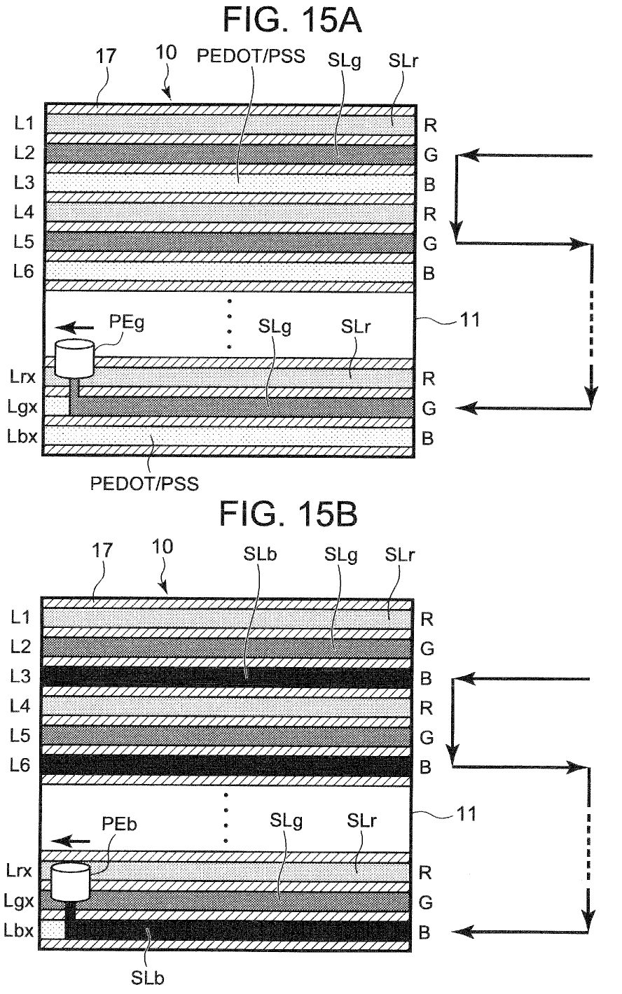

Further, FIGS. 14A and 14B and FIGS. 15A and 15B are diagrams for explaining the film forming process of the electron transporting light emitting layer by the film forming process and the manufacturing apparatus of the first configuration in the manufacturing method of the display apparatus (display panel) according to the embodiment. Here, in order to clearly define the drawing, hatchings are conveniently carried out to each column in which the ink application treatment is carried out.

As for the film forming process of the organic EL layer according to the structure, in the above described manufacturing method of the display panel, first, for example, polyethylenedioxythiophene/polystyrenesulphonic acid aqueous solution (PEDOT/PSS; a dispersion liquid in which polyethylenedioxythiophene PEDOT which is the conductive polymer and polystyrenesulphonic acid PSS which is a dopant are dispersed in aqueous medium) is applied as an organic compound containing solution including an organic polymer hole transporting material on the pixel electrode 15 (transparent electrode layer 15b) which is exposed at the EL element forming region Rel defined by the bank 17 by using the nozzle print film forming apparatus. Thereafter, the solvent is removed by carrying out the heat-dry treatment. Thereby, the organic polymer hole transporting material is fixed on the pixel electrode 15 to form the hole transporting layer 18a which is the carrier transporting layer having a predetermined film thickness.

As shown in FIG. 11A and the like, the manufacturing apparatus of the structure comprises a nozzle print film forming device having one printer head PH and a moving device to move either one of the printer head PH of the nozzle print film forming device or the substrate 11, and is constructed so as to carry out the applying in a predetermined order to each column by the printer head PH.

In particular, the manufacturing apparatus for carrying out the film forming process of the first configuration is constituted as shown in FIG. 12A or FIG. 12B, for example.

The manufacturing apparatus shown in FIG. 12A comprises a substrate stage 20 to mount the substrate 11, a stage moving mechanism unit 21 so as to move the substrate stage 20 in the XY direction (XY direction is a direction parallel to the mounting surface of the substrate stage 20), a print head unit 22 having one print head PH and a control unit 23. The control unit 23 controls the moving direction, the moving amount, the moving speed and the like of the substrate stage 20 by the substrate stage moving mechanism unit 21 via the substrate stage moving control unit 24. Further, for example, the manufacturing apparatus comprises a position adjustment detection unit 25 which detects the position adjusting mark provided on the substrate 11, and the control unit 23 controls the moving amount and the like of the substrate stage 20 by the substrate stage moving mechanism unit 21 based on the detection result by the position adjustment detection unit 25. Further, the control unit 23 controls the amount of liquid that is discharged from the printer head PH of the print head unit 22. Here, the print head unit 22 and the control unit 23 forms the nozzle print film forming device, and the substrate stage 20, the control unit 23, the substrate stage moving mechanism unit 21, the substrate stage moving control unit 24 and the position adjustment detection unit 25 form the moving device.

Moreover, the manufacturing apparatus shown in FIG. 12B comprises the substrate stage 20 to mount the substrate 11, the print head unit 22 having one printer head PH, the print head moving mechanism unit 26 so as to move the print head unit 22 in the XY direction (XY direction is a direction parallel to the mounting surface of the substrate stage 20) and the control unit 23. Further, the control unit 23 controls the moving direction, the moving amount, the moving speed and the like of the print head unit 22 by the print head moving mechanism unit 26 via the print head moving control unit 27. Furthermore, the manufacturing apparatus shown in FIG. 12B comprises the position adjustment unit 25 in a similar manner to the FIG. 12A, and the control unit 23 controls the moving amount and the like of the print head unit 22 by the print head moving mechanism unit 26 based on the detection result by the position adjustment detection unit 25. Here, the print head unit 22 forms the nozzle print film forming device, and the substrate stage 20, the control unit 23, the print head moving mechanism unit 26, the print head moving control unit 27 and the position adjustment detection unit 25 form the moving device of the present invention.

In either of the structures of FIG. 12A and FIG. 12B, the manufacturing apparatus can move the print head PH relatively to a predetermined position with respect to the substrate 11, and can apply the liquid to a predetermined position on the substrate 11 by moving the substrate 11 while discharging the liquid from the print head PH.

In the applying method of the organic compound containing solution including the hole transporting material by the manufacturing apparatus, the above PEDOT/PSS is made to be in a liquid form of a predetermined amount and is discharged from the outlet of the printer head PH of the nozzle print film forming apparatus, and is applied to the EL element forming region Rel of the column in which the color pixels in same color (for example, color pixel PXr of red (R) color) are arranged by orderly moving (scanning) the printer head PH in a predetermined speed by the substrate stage moving mechanism unit 21 or the print head moving mechanism unit 26. At this time, the liquid flow of the PEDOT/PSS applied to the EL element forming region Rel is repelled even when the PEDOT/PSS is dropped on the bank 17 because the repellency treatment is carried out to the surface of the bank 17 as described above, and the solution is blended and spread on each pixel electrode 15 in which the lyophilic treatment is carried out.

Here, the control of the flow volume of the PEDOT/PSS which is discharged from the printer head PH by the control unit 23 may be adjusted by controlling the frequency (discharge amount) of the discharge pump of the nozzle print film forming device, for example, or may be adjusted by changing the size (nozzle diameter) of the output of the printer head PH.

Hereinafter, the film forming process of the organic EL layer in the structure will be described. In the description hereinafter, the operation of each unit which constitutes the manufacturing apparatus is controlled by the control unit 23.

In particular, in the film forming process of the organic EL layer in the structure, as shown in FIG. 11A, first, the PEDOT/PSS which is made to be in a liquid form in the first flow volume is discharged to the insulative substrate 11 mounted on the substrate stage 20 of the nozzle print film forming apparatus and is continuously applied to the EL element forming region Rel of the first line (first column) L1 (hereinafter, conveniently described as “the first moving of hole layer (red)”) while moving the print head PH relatively in the column direction (top-down direction in drawing in the display panel 10 shown in FIG. 1, however, left-right direction in drawing in FIGS. 11A and 11B due to the convenience of the drawing) along the first line L1 in which the color pixels PXr of color red (R) of the first line of the display panel 10, for example.

Next, the substrate stage 20 is moved relatively for three lines length (three columns length) in the direction orthogonal (row direction; upper side in the drawing) to the moving direction (column direction) of the printer head PH as shown in FIG. 11B. Then, the printer head PH is moved to a position corresponding to the fourth line (forth column) L4 in which the color pixels PXr of red (R) color of fourth line of the display panel 10 are arranged. Thereafter, in a similar way as in the first moving of hole layer (red), the PEDOT/PSS is made to be in a liquid form in the first flow volume and is discharged and continuously applied to the EL element forming region Rel of the fourth line L4 while moving the printer head PH relatively in the column direction (hereinafter, conveniently described as “the second moving of hole layer (red)”).

After applying the PEDOT/PSS while moving the printer head PH in the column direction in such way, the printer head PH is moved for a predetermined pitch (three lines length) in the row direction, and the PEDOT/PSS is also applied to the EL element forming region Rel in which the color pixels PXr of red (R) color is arranged which are the seventh line (seventh column) L7, the tenth line (tenth column) L10, the thirteenth line (thirteenth column) L13 . . . (third moving of hole layer (red) . . . ) by orderly repeating the series of operations of applying the PEDOT/PSS as shown in FIG. 11B.

Subsequently, as shown in FIG. 13A, the substrate stage 20 is moved relatively in the row direction with respect to the printer head PH and the printer head PH is moved to a position corresponding to the second line (second column) L2 in which the color pixels PXg of green (G) color of the second line of the display panel 10 are arranged with respect to the insulative substrate 11. Thereafter, the PEDOT/PSS is made to being liquid form of the second flow volume and is discharge and continuously applied to the EL element forming region Rel of the second line L2 while moving the printer head PH relatively in the column direction (hereinafter, conveniently described as “the first moving of hole layer (green)”).

At this time, the PEDOT/PSS applied to the EL element forming region Rel of the first line (first column) L1 of the display panel 10 (insulative substrate 11) by the first moving of hole layer (red) is sufficiently dried by heating while the applying operation after the second moving of hole layer (red) is being executed by heat-drying the substrate stage 20 in which the insulative substrate 11 is mounted at a predetermined temperature to form the hole transporting layer 18a in which the hole transporting material is fixed in a thin film form in the EL element forming region Rel of the color pixels PXr of red (R) color including the top portion of the pixel electrode 15 (transparent electrode layer 15b). Here, when the condition such as the scanning speed (applying speed) of the printer head PH, the heating temperature of the substrate stage 20 and the like is set to a specific fixed value and when only the flow volume of the PEDOT/PSS is set to be arbitrary, the film thickness of the hole transporting layer 18a formed on the pixel electrode 15 (transparent electrode layer 15b) of the color pixel PXr of red (R) color is decided depending on the flow volume (the first flow volume; corresponding to the applied amount) of the PEDOT/PSS discharged from the printer head PH and is formed to have a film thickness of tens of nm order, for example.

Next, in a similar way as the second moving of hole layer (red), the substrate stage 20 (insulative substrate 11) is relatively moved for three lines length (three columns length) in the direction (row direction) orthogonal with respect to the moving direction (column direction) of the printer head PH. Further, the printer head PH is moved to a position corresponding to the fifth column L5 in which the color pixels PXg of green (G) color in the fifth line (fifth column) of the display panel 10 are arranged. Thereafter, in a similar way as the first moving of hole layer (green), the PEDOT/PSS is made to be in a liquid form of the second flow volume and is discharged and continuously applied to the EL element forming region Rel of the fifth line L5 while moving the printer head PH relatively in the column direction (hereinafter, conveniently described as “the second moving of hole layer (green)”).

Hereinafter, in a similar way as after the third moving of hole layer (red), the PEDOT/PSS is applied while moving the printer head PH in the column direction. Thereafter, the printer head PH is moved for a predetermined pitch (three lines length) in the row direction, and the PEDOT/PSS is also applied to the EL element forming region Rel in which the color pixels PXg of green (G) color are arranged which are the eighth line (eighth column) L8, the eleventh line (eleventh column) L11, the fourteenth line (fourteenth column 14) L14 . . . (third scanning of hole layer (red) . . . ) by orderly repeating the series of operations of applying the PEDOT/PSS (the third scanning of hole layer (green) . . . ).

Further, as shown in FIG. 13B, the PEDOT/PSS is made to be in a liquid form of the third flow volume and is discharged and applied to each line in which the color pixels PXb of blue (B) color are arranged, that is, to the third line (third column 3) L3, the sixth line (sixth column) L6, the ninth line (ninth column) . . . in a similar way as the EL element forming region Rel in which the color pixels PXr, PXg of red (R) and green (G) are arranged by moving the printer head PH in the column direction. Thereafter, the printer head PH is moved by a predetermined pitch (three lines length) in the row direction and the PEDOT/PSS is also applied to the EL element forming region Rel in which the color pixels PXb of blue (B) color are arranged by orderly repeating the series of operation of applying the PEDOT/PSS (the first moving of hole layer (blue) . . . ).

In such way, the hole transporting layer 18a having a predetermined film thickness is formed on the pixel electrodes 15 (transparent electrode layer 15b) from which the EL element forming region Rel in which the color pixels PXg of green (G) and the color pixels PXb of blue (B) are arranged are exposed depending on the flow volume of the PEDOT/PSS discharged from the printer head PH, that is the hole transporting layer 18a having a predetermined film thickness the formed by depending on the second low volume and the third flow volume. Here, any of the hole transporting layers 18a formed on the pixel electron 15 of the color pixel PXg of green (G) and the color pixel PXb of blue (B) have the film thickness of about tens to 100 nm, for example.

Next, at the EL element forming region Rel in which the hole transporting layer 18a is formed for each color pixel PXr, PXg and PXb, a solution (hereinafter, described as “light emitting material solution”) in which the light emitting material corresponding to each luminescent color of red (R), green (G) and blue (B) including a conjugate double bond polymer such as polyparaphenylene-vinylene, polyfluorene or the like is dissolved in organic solvent such as tetralin, tetramethylbenzene, mesitylene, xylene or the like or water is applied on the hole transporting layer 18a as the organic compound containing solution including an organic polymer electron transporting light emitting material. Thereafter, by removing the solvent by carrying out the heat-dry treatment, the organic polymer electron transporting light emitting material is fixed on the hole transporting layer 18a to form the electron transporting light emitting layer 18b which is a carrier transporting layer and is also a light emitting layer.

Here, in a similar manner as the above described applying method of the PEDOT/PSS (organic compound containing solution including hole transporting material) when forming the hole transporting layer 18a, in the applying method of the organic compound containing solution including the electron transporting light emitting material, the light emitting material solution corresponding to each luminescent color is made to be in a liquid form and is discharged from the output of the printer head of the nozzle print film forming device, and is applied to the EL element forming region Rel of the line in which the color pixels of the same color (for example, the color pixels PXr of red (R) color) are arranged while orderly moving the printer head. At this time, as described above, the liquid flow of the light emitting material solution applied to the EL element forming region Rel is repelled even when the solution is dropped on the bank 17 because the repellency treatment is carried out to the surface of the bank 17, and the solution is blended and spread on the hole transporting layer 18a having the lyopholic characteristic.

In particular, first, the light emitting material solution is made to be in a liquid form in a predetermined flow volume and is discharged and continuously applied to the EL element forming region Rel of the first column L1 while moving the printer head PEr which discharges the light emitting material solution corresponding to the luminescent color of red (R) relatively in the column direction (left-right direction in the drawing) along the first column L1 in which the color pixels PXr of red (R) color are arranged of the display panel 10 with respect to the insulative substrate 11 mounted on the substrate stage 20 of the nozzle print film forming device as shown in FIG. 14A (hereinafter, conveniently described as “first moving of light emitting layer (red)”).

Next, the substrate stage 20 (insulative substrate 11) is relatively moved in the direction (row direction; upper direction in the drawing) orthogonal to the moving direction (column direction) of the printer head PEr for three lines length (three columns length). After, the printer head PEr is moved to a position corresponding to the fourth line L4 in which the color pixels PXr of red (R) color of the fourth line are arranged of the display panel 10, the light emitting material solution is made to be in a liquid form in a predetermined flow volume and is discharged and continuously applied to the EL element forming region Rel of the fourth line L4 by moving the printer head PEr relatively in the column direction similarly to the first moving of light emitting layer (red) (the second moving of light emitting layer (red)).

Hereinafter, in a similar way, the light emitting material solution is orderly applied to the EL element forming region Rel of each line while moving the printer head PEr along the lines 7, 10, 13 . . . of the display panel 10 as shown in FIG. 14B (the third moving of light emitting layer (red) . . . ). That is, the light emitting material solution is applied to the EL element forming region Rel for every three lines which are in same color.

Subsequently, the printer head PEg is moved to a position corresponding to the second line L2 in which the color pixels PXg of green (G) color of the second line are arranged in the display panel 10 with respect to the insulative substrate 11 as shown in FIG. 15A. Thereafter, in a similar manner as the above described first moving of light emitting layer (red), the light emitting material solution is applied to the EL element forming region Rel of the second line L2 while moving the printer head PEg in the column direction. Thereafter, the printer head PEg is moved in the row direction for a predetermined pitch (for three lines length), and the light emitting material solution is orderly applied to the EL element forming region Rel in which the color pixels PXg of green (G) color are arranged which are the second line (second column) L2, the fifth line (fifth column) L5, the eighth line (eighth column) L8 . . . by orderly repeating the series of operations of applying the light emitting material solution (the first moving of light emitting layer (green) . . . ).

Further, in a similar manner as the above described operation following the first moving of light emitting layer (red), the light emitting material solution is also applied to the EL element forming region Rel of the third line (third column 3) L3, the sixth column (sixth column) L6, the ninth line (ninth column) L9 . . . in which the color pixels PXb of blue (B) color are arranged of the display panel 10 while moving the printer head PEb in the column direction as shown in FIG. 15B. Thereafter, the printer head PEb is moved in the row direction for a predetermined pitch (for three lines length), and the series of operations of applying the light emitting material solution is orderly repeated.

In such way, the electron transporting light emitting layer 18b having a predetermined film thickness is formed on the hole transporting layer 18a of each EL element forming region Rel in which the color pixels PXr, PXg or PXb of each color red (R), green (G) and blue (B) are arranged. Here, the electron transporting light emitting layer 18b formed in the color pixels PXr, PXg and PXb of each color is formed by having the film thickness of about tens to 100 nm, for example.

Therefore, by such film forming process of the organic EL layer, the organic EL layer 18 having at least the hole transporting layer 18a having different film thickness for each color of red (R), green (G) and blue (B) and the electron transporting light emitting layer 18b having a predetermined film thickness corresponding to each luminescent color of red (R), green (G) and blue (B) is formed at the EL element forming region Rel in which each color pixels PXr, PXg and PXb are arranged of the display panel 10 as shown in FIGS. 4, 5A, 5B and 9.

### (The Second Configuration of the Film Forming Process and the Manufacturing Apparatus)

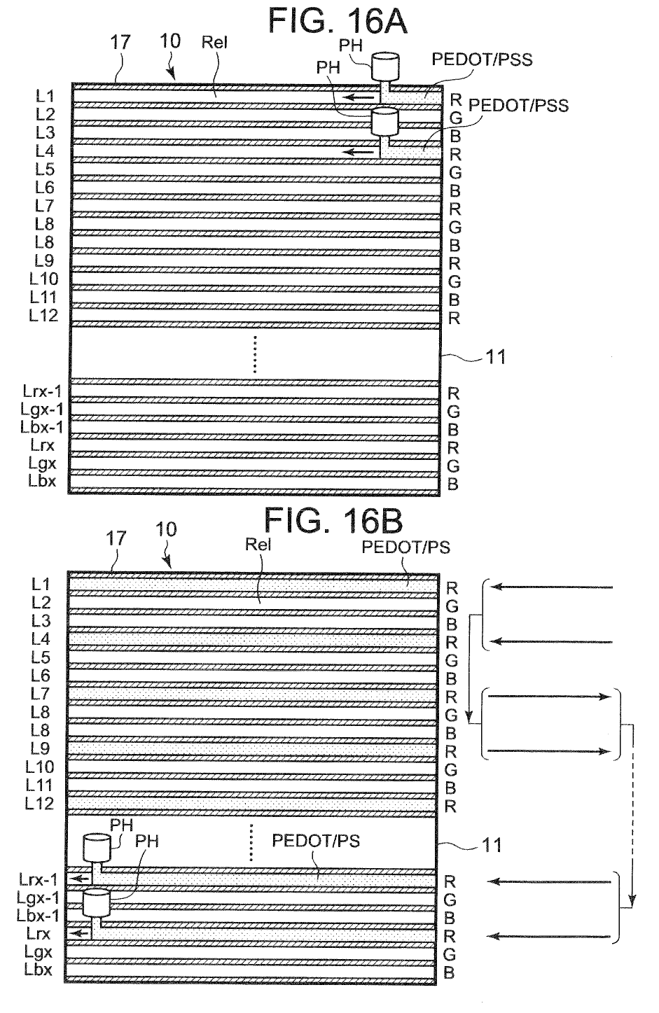

FIGS. 16A and 16B are diagrams for explaining the film forming process of the hole transporting layer by the second configuration of the film forming process and the manufacturing apparatus in the manufacturing method of the display apparatus according to the embodiment.

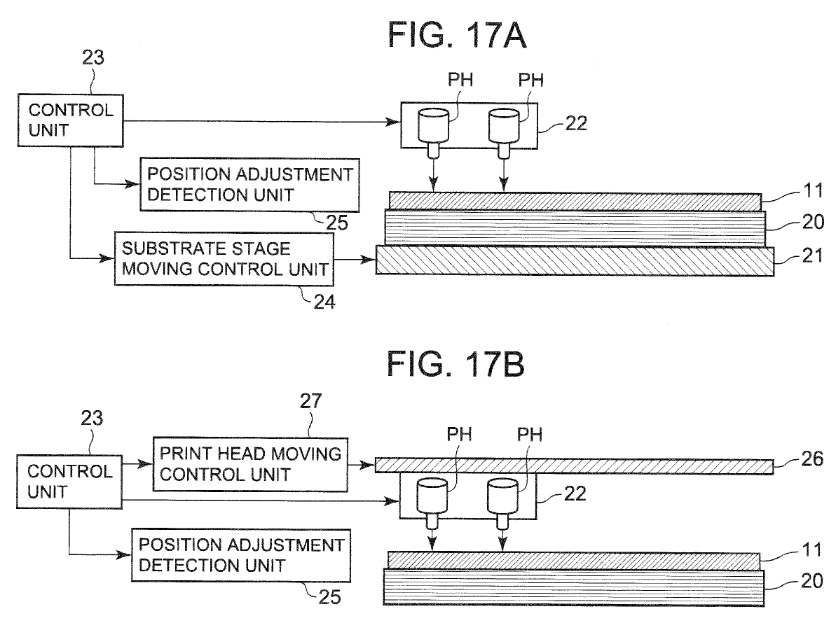

FIGS. 17A and 17B are diagrams showing an example of a structure of the manufacturing apparatus for carrying out the second configuration of the manufacturing method of the display apparatus according to the embodiment.

In the above described first configuration of the film forming process and the manufacturing apparatus, the nozzle print film forming device comprises one printer head PH, and the solution is applied to every three lines in the display panel 10 by moving the printer head PH by three lines based on the arrangement of each color of R, G and B of the substrate 11. On the other hand, the second configuration of the film forming process and the manufacturing apparatus of the second configuration differs from the first configuration in that the nozzle print film forming device comprises a plurality of, that is, 2 or more printer heads PH and the solution is simultaneously applied to a plurality of lines in which the color pixels of the same color are arranged.

In the manufacturing apparatus of the structure, the nozzle print film forming device comprises two printer heads PH which are provided so as to correspond to two lines which are the two lines of the every other lines in the display panel 10, for example, as shown in FIG. 16A. In such way, the solution can be simultaneously applied to the two lines in which the color pixels of the same color are arranged in the display panel 10.

In particular, the manufacturing apparatus for carrying out the second configuration of the film forming process is structured as shown in FIG. 17A or in FIG. 17B, for example.

The structures shown in FIGS. 17A and 17B differ from the structures shown in FIGS. 12A and 12B in that the print head unit 22 comprises two printer heads PH and that the control unit 23 controls the liquid amount to be discharged from each printer head PH. As for the other structure, the structures shown in FIGS. 17A and 17B are same as the structures shown in FIGS. 12A and 12B. Therefore, the explanations are omitted.

In the manufacturing apparatus, the two printer heads PH can be relatively moved to a predetermined position with respect to the substrate 11, and the liquid can be simultaneously applied to two positions on the substrate 11 which are predetermined by moving the two printer heads PH while the liquid is discharged from the printer heads PH in either of the structures of FIGS. 17A and 17B.

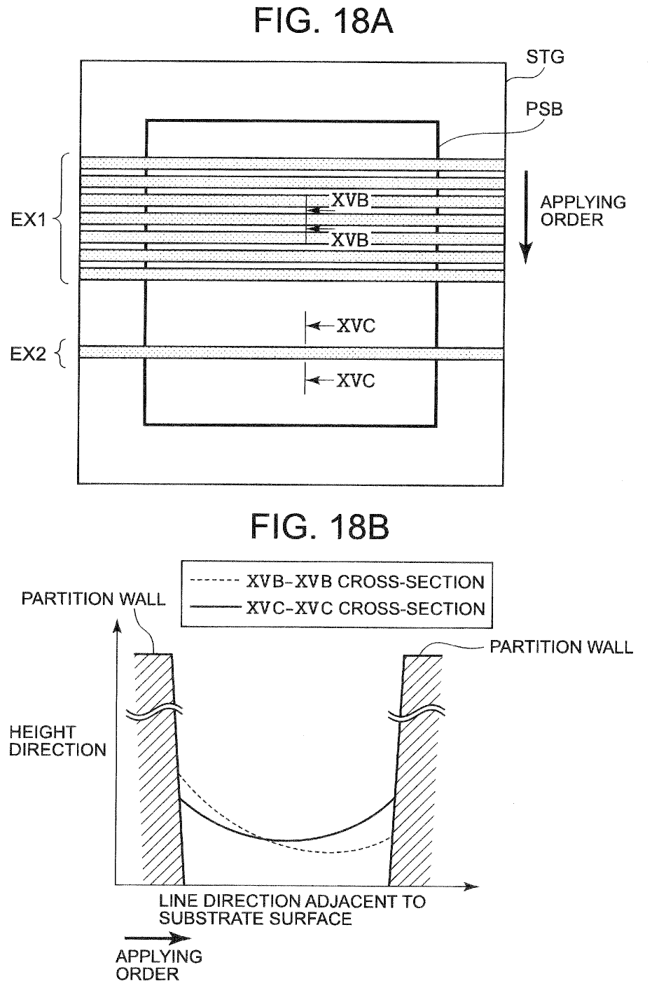

Here, in FIGS. 16A and 16B and in FIGS. 17A and 18B, the print head unit 22 of the nozzle print film forming device comprises two printer heads PH. However, the present invention is not limited to this, and the print head unit 22 may comprise a plurality of printer heads PH, that is, two or more printer heads PH, and the solution may be simultaneously applied to a plurality of lines which is the same number as the number of printer heads PH of the print head unit 22.

Hereinafter, the applying method of the organic compound containing solution by the nozzle print film forming device of the structure will be described. Here, operation of each unit constituting the manufacturing apparatus is controlled by the control unit 23.

In the applying method of the organic compound containing solution by the nozzle print film forming device structure of the structure, first, the PEDOT/PSS is made to be in a liquid form in the first flow volume and is discharged and simultaneously and continuously applied to the EL element forming region Rel of the first line (first column) L1 and the fourth line (fourth column) L4 while moving the two printer heads PH relatively in the column direction along the first line L1 and the fourth line L4 in which the color pixels PXr of red (R) color, for example, are arranged in the display panel 10 with respect to the insulative substrate 11 mounted on the substrate stage 20 of the nozzle print film forming device as shown in FIGS. 16A and 16B (the first moving).

Next, the substrate stage 20 (insulative substrate 11) is moved relatively in the direction orthogonal (row direction; upper direction in the drawing) with respect to the moving direction (column direction) of the printer head PH for three lines length (three columns length) as shown in FIG. 16B. In such way, the two printer heads PH are moved to the positions corresponding to the seventh line L7 and the tenth line L10 in which the color pixels PXr of red (R) color are arranged in the display panel. Thereafter, in a similar manner as the above described first moving, the PEDOT/PSS is made to be in a liquid form in the first flow volume and is discharged and simultaneously and continuously applied to the EL element forming regions Rel of the seventh line L7 and the tenth line L10 in the display panel 10 while moving the two printer heads PH relatively in the column direction (the second moving).

By repeating the above series of operations, the PEDOT/PSS is applied to the EL element forming region Rel of each line in which the color pixels PXr of red (R) color are arranged in the display panel 10.

Hereinafter, in a similar manner as the above described first moving and second moving, each printer head PH is moved with respect to each line in which the color pixels PXg of green (G) color are arranged in the display panel 10, and the PEDOT/PSS is made to be in a liquid form and is discharged from each printer head PH to be continuously applied to the EL element forming regions Rel. Next, each printer heads PH is moved with respect to each line in which the color pixels PXb of blue (B) color are arranged in the display panel 10, and the PEDOT/PSS is made to be in a liquid form in the third flow volume and is discharged from each printer head PH to be continuously applied to the EL element forming regions Rel.

Next, in a similar manner as shown in FIGS. 14A, 14B and in FIGS. 15A, 15B, the organic compound containing solution including the electron transporting light emitting material of the corresponding color is applied by each printer head PH to the EL element forming regions Rel in which the hole transporting layer 18 a of each line in which each color pixels PXr, PXg and PXb are arranged in the display panel 10.

In such way, similarly to the case of the film forming process of the first embodiment, the organic EL layer 18 comprising at least the hole transporting layer 18a having film thickness which is different of each color of red (R), green (G) and blue (B) and the electron transporting light emitting layer 18b having a predetermined film thickness corresponding to each luminescent color of red (R), green (G) and blue (B) is formed at the EL element forming regions Rel in which each color pixels PXr, PXg and PXb are arranged in the display panel 10.

In the embodiment, the nozzle print film forming device comprises a plurality of printer heads PH, and the time needed for applying the solution to all of the lines in the display panel 10 can be shortened comparing to the case of the first embodiment where only one printer head PH is provided because the solution can be simultaneously applied to a plurality of lines of the same color in the display panel 10.

### <Verification of the Manufacturing Method>

Here, the effect of the above described film forming process will be described in detail by showing the experimental results.

FIGS. 18A and 18B are schematic diagrams showing the verification result of the effect of the manufacturing method (the film forming process of the organic EL layer) of the display apparatus according to the embodiment.

Here, FIG. 18A is a schematic planar diagram showing the ink applying method which is carried out to the panel substrate. P FIG. 18B is a schematic cross-sectional diagram showing the cross-section surface cut along the line XVB-XVB and the line XVC-XVC (in the specification, “XV” is conveniently used as a symbol corresponding to the roman numeral “15” shown in FIGS. 18A and 18B) in the planar diagram shown in FIG. 18A. Further, in FIG. 18A, the lines (columns) in which the applying treatment of the organic compound containing solution is carried out is shown by using hatchings in order to clarify the drawings.

Here, the film thickness and the shape (profile) of the cross-section of the film in a case where the applying treatment of the high polymer organic compound containing solution (corresponding to the above mentioned PEDOT/PSS or the light emitting material solution) is orderly carried out continuously to the lower direction of the drawing from the line in the upper side of the drawing (EX1 in the drawing) to the lines which are adjacent to one another among the lines including the EL element forming region Rel of each color which is set in one surface side of the panel substrate PSB (corresponding to the above mentioned insulative substrate 11) which is mounted or fixed on the substrate stage STG of the nozzle print film forming device and in a case where the applying treatment of the above mentioned organic compound containing solution is only carried out to a specific one line and the applying treatment is not carried out to the adjacent lines (EX2 in the drawing) will be tested as shown in FIG. 18A as an experimental model corresponding to the display apparatus (display panel) shown in the above described embodiment.

Moreover, a case where the display panel in which the pixel density is set to 80 ppi (pixel per inch), the number of lines in which the organic compound containing solution is applied is set to 420 lines and the pitch between the lines is set to 318 μm is applied as an experimental model and where the organic compound containing solution is applied to the panel substrate PSB mounted on the substrate stage STG which is heated to 40 degrees by the applying method shown in the above described film forming process was tested.

In the former applying treatment (EX1), regarding the film thickness and the shape of the cross-section of the film of the organic film (corresponding to the above mentioned hole transporting layer 18a or electron transporting light emitting layer 18b) which is formed at the EL element forming region Rel of each line, the film thickness will be uneven in the line direction in which the deposit of the organic compound containing solution is at the side due to the unevenness of the localized solvent atmosphere in the direction of adjacent lines (left direction in FIG. 18B) which occurs due to the difference in the timing that the organic compound containing solvent is dried in the line in which the solution is applied first and in the line in which the solution is applied afterwards, where the organic compound containing solution is continuously applied to the lines shown in FIG. 18B after the organic compound containing solvent is applied to the line (omitted from the drawing) in the left side of the line shown in FIG. 18B effecting the drying property of the organic compound containing solution as shown as the cross-section cut along the dotted-line XVB-XVB in FIG. 18B. That is, the film surface greatly rises to the wall surface in the partition wall side (in left side of FIG. 18B) in the side of the line in which the solution is applied first, and the rising of the film surface is suppressed to be small in the other partition wall side (in right side of FIG. 18B) and a phenomenon in which the shape of the cross-section of the film is greatly biased was found.

In other hand, as for the film thickness and the shape of the cross-section of the film in the latter applying treatment (EX2), the subsequent applying treatment is not carried out to the adjacent lines after the organic compound containing solution is applied to a specific line as shown as the cross-section cut along the line XVC-XVC in FIG. 18B. Therefore, the effect to the drying property of the organic compound containing solution can be eliminated and the organic compound containing solution applied to the specific line can be sufficiently dried to make the film thickness be approximately even. Further, it is found that the shape of the cross-section of the film can be made to be approximately even.

That is, when there is a space between the specific line and the line in which the applying treatment is continued after the applying treatment of the organic compound containing solution is carried out to the specific line so as not to effect the drying property of the organic compound containing solution and when the applying treatment is carried out to the line adjacent to the specific line, the evenness of the film thickness and the shape of the cross-section of the film of the organic film (hole transporting layer 18a and electron transporting light emitting layer 18b) formed at the EL element forming region Rel of each display pixel can be improved by setting the manufacturing condition so that the time which is sufficient to dry the organic compound containing solution applied to the specific line will elapse.

Particularly, by applying such manufacturing method, the hole transporting layer 18a for each color of RGB can be formed so as to have an even film thickness and to have good flatness in the display apparatus (display panel) having the organic EL element OLED in which the organic EL layer 18 is formed by applying the high polymer organic compound containing solution. Further, the film thickness can be controlled accurately and the desired value can be set by controlling the applying amount of the solution.

Here, in the manufacturing method (the film forming process of the organic EL layer) shown in the above embodiment, a case where the organic compound containing solution such as the PEDOT/PSS, the light emitting material solution or the like is applied every three lines based on the arrangement of each color of RGB is described. However, the present invention is not limited to this. The organic compound containing solution can be applied for every arbitrary lines which is the integral multiple of three (for example, for every six lines or for every twelve lines) based on the manufacturing condition such as the easiness of drying of the organic compound containing solution which is applied, the temperature of the panel substrate in the film forming process.

Moreover, in the above described film forming process, a case where the film thicknesses of the hole transporting layer and the electron transporting light emitting layer are adjusted (controlled) according to the flow volume of the organic compound containing solution (the PEDOT/PSS or the light emitting material solution) discharged from the printer head. However, the present invention is not limited to this.

For example, the film thickness may be adjusted by changing the moving speed (the relative moving speed with respect to the substrate stage STG, and which corresponds to the applying speed) of the printer head in a state where the low volume is constant.

Further, the film thickness may be adjusted by arbitrarily setting both of the flow volume and the moving speed.

Furthermore, the film thickness may be adjusted by changing the number of lines of applying (the number of times of moving of the printer head) to each line (that is, applying for two time, applying for three times and the like) when the flow volume and the moving speed is constant.

Further, the film thickness may be adjusted by the combination of the above.

### <Verification of the Display Apparatus>

Next, the effect of the display apparatus (display panel) which is manufactured by using the above described manufacturing method will be verified by showing the test results.

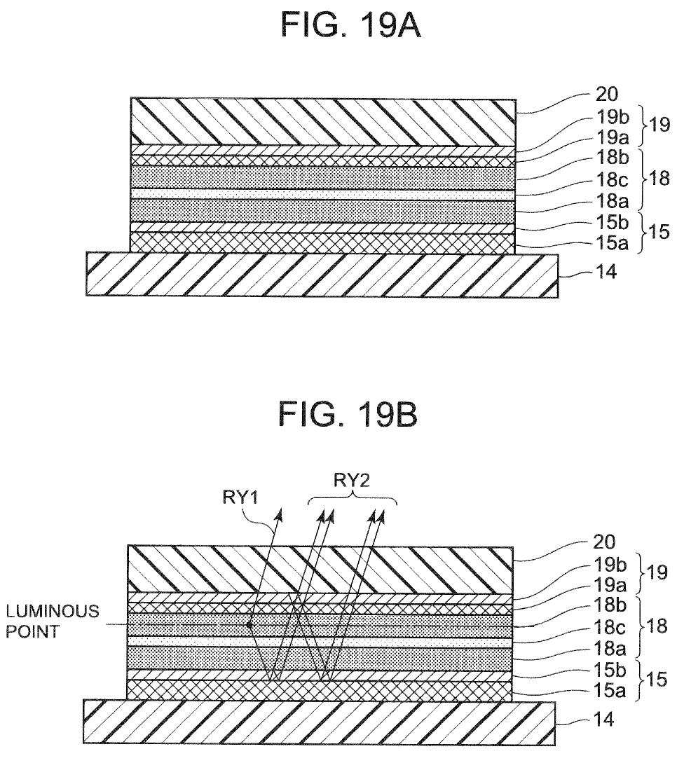

FIGS. 19A and 19B are a schematic diagram showing an example (experimental model) of the element structure of the organic EL element which is formed in the display apparatus (display panel) according to the embodiment and a diagram for explaining the interference effect. Here, the element structure of the organic EL element which emits blue light is shown as an experimental model.

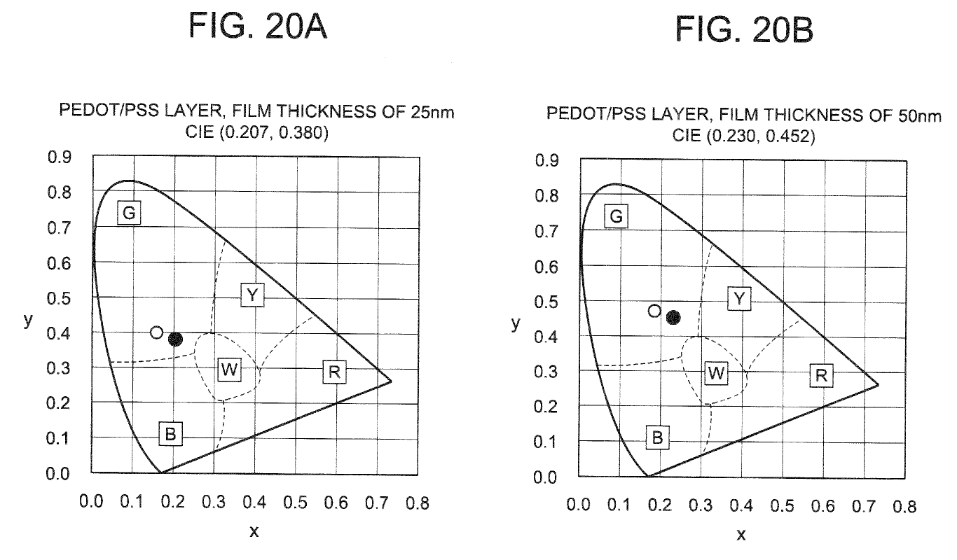

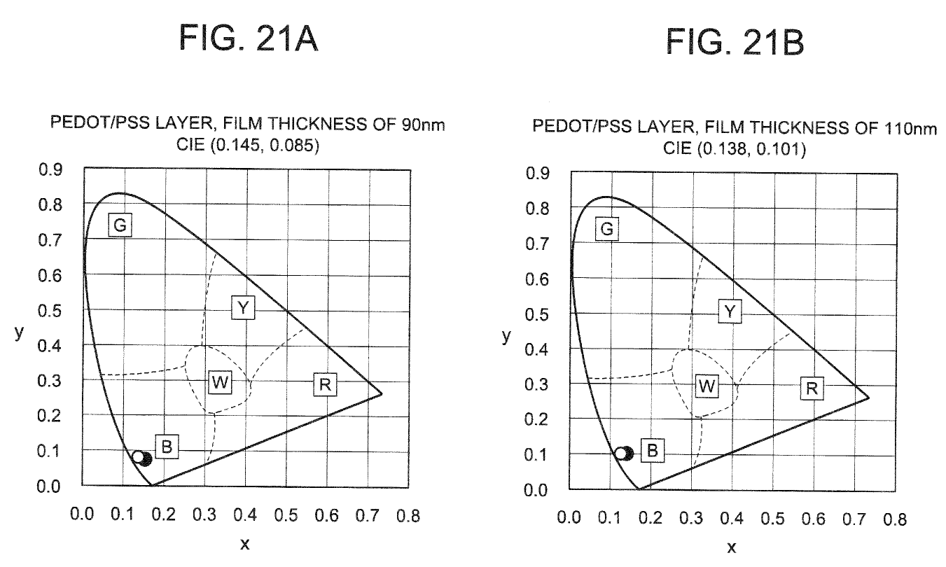

FIGS. 20A, 20B and FIGS. 21A, 21B are chromaticity diagrams showing a relation between the film thickness and the chromaticity of the hole transporting layer in the organic EL element which emits blue light formed in the display apparatus (display panel) according to the embodiment.

Here, regarding the chromaticity when the film thickness of the hole transporting layer is changed, both of the observation result (observation result; shown by a black dot in the drawing) when the organic EL element having the element structure shown in FIG. 19A is actually prepared and observed and the simulation experimental result (simulation result; shown by white dot in the drawing) based on various types of parameters according to the element structure are shown.

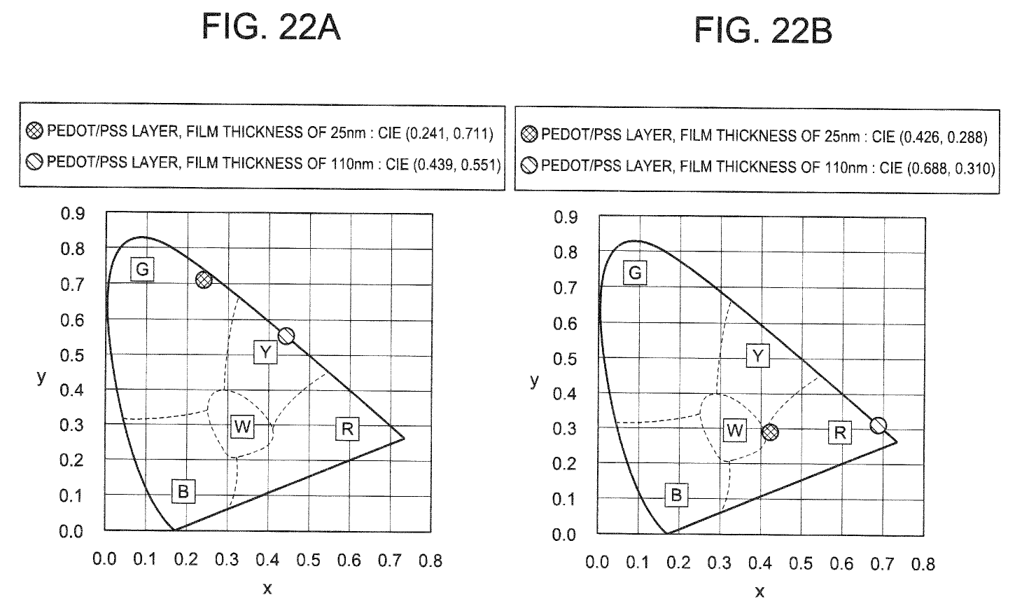

Further, FIGS. 22A, 22B are chromaticity diagrams showing a relation between the film thickness and the chromaticity of the hole transporting layer in the organic EL element which emits green line and the organic EL element which emits red light which are formed in the display apparatus (display panel) according to the embodiment.

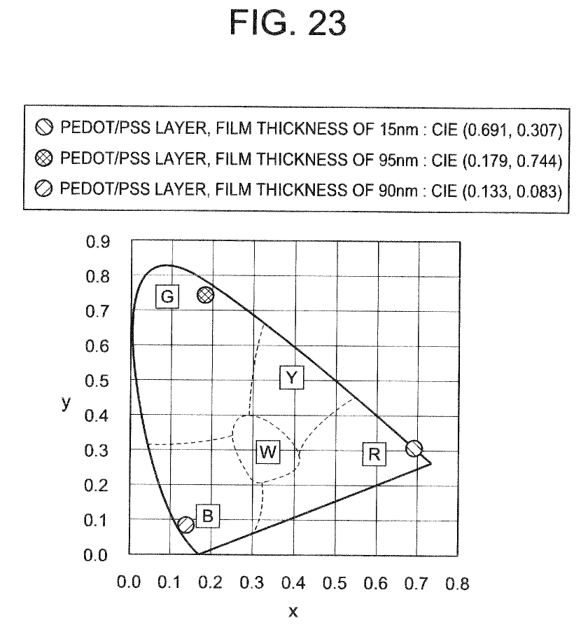

FIG. 23 is a chromaticity diagram showing a relation between the film thickness and the luminescent chromaticity of the hole transporting layer in the organic EL element which is formed in the display apparatus (display panel) according to the embodiment.

Here, regarding the chromaticity when the film thickness of the hole transporting layer is changed, the result of simulation experiment (simulation result) based on various types of parameters according to the element structure of the organic EL element shown in FIG. 19A is shown.

In the above described verification of the effect of the display apparatus according to the embodiment, the chromaticity of the light which is emitted at the time of light emitting operation is observed by applying the organic EL element OLED having an element structure in which the pixel electrode 15 constituted of the reflection layer 15a formed of aluminum (Al) and silver (Ag) and the transparent electrode layer 15b formed of the ITO which covers the reflection layer 15a, the hole transporting layer 18a formed by applying the PEDOT/PSS, the inter-layer (inserting layer) 18c having an electron blocking characteristic, the light emitting layer (or electron transporting light emitting layer) 18b formed by applying the light emitting material solution corresponding to the blue luminescence, the electron injection layer 19a formed of a thin film of calcium (Ca), the transparent electrode layer 19b formed of the ITO and the sealing film (passivation film) 20 formed of a nitride silicon film are orderly layered on the flattening layer 14 formed of a nitride silicon film as an experimental model as shown in FIG. 19A.

Here, the experimental model shown in FIG. 19A is generally prepared by a manufacturing process as described hereinafter.

First, the flattening film 14 formed of a nitride silicon film is formed on the insulative substrate (insulative substrate 11) which is omitted from the drawing, and the surface of the aluminum thin film is cleansed by oxygen (O₂) plasma and silver (Ag) is vacuum-diposited on the cleansed aluminum thin film in the film thickness of 100 nm after forming a thin film of aluminum (Al) on the flattening film 14. Thereby, the reflection layer 15a in which the surface has a metallic luster (that is, light reflecting characteristic) due to silver is formed.

Subsequently, a film of the ITO is formed on the reflection layer 15a by the target spattering method in the film thickness of 25 nm to form the transparent electrode layer 15b which covers the surface of the reflection layer 15a.

Next, after making the surface of the transparent electrode layer 15b have lyophilic characteristic by carrying out cleansing to the surface of the transparent electrode layer 15b by UV ozone, the hole transporting layers 18a having different film thicknesses for each color are formed by applying the PEDOT/PSS and drying by the spin coat method.

Here, in the above described embodiment, when a plurality of applying lines (corresponding to the region constituted of a plurality of EL element forming region Rel which are enclosed by the bank 17) are set in one surface side of the insulative substrate 11, the hole transporting layer 18a is formed by making the organic compound containing solution be in a liquid form and continuously applying the solution by the nozzle print film forming apparatus as described above. However, here, a case where the hole transporting layers 18a having an arbitrary film thickness for each color are formed by applying the PEDOT/PSS by the spin coat method is conveniently shown as an experimental model.

In particular, in the organic EL element OLED shown in FIG. 19A, the solid content concentration of the PEDOT/PSS is set to 1.4% and the rotation frequency of the substrate is set to 800 rpm for 5 sec, further, 4500 rpm for 20 sec as the condition for forming the hole transporting layer 18a having a film thickness of 25 nm. Further, the solid content concentration of the PEDOT/PSS is set to 1.4% and the rotation frequency of the substrate is set to 800 rpm for 5 sec, further, 2000 rpm for 20 sec as the condition for forming the hole transporting layer 18a having a film thickness of 50 nm. Furthermore, the solid content concentration of the PEDOT/PSS is set to 2.8% and the rotation frequency of the substrate is set to 800 rpm for 5 sec, further, 3000 rpm for 20 sec as the condition for forming the hole transporting layer 18a having a film thickness of 90 nm. Moreover, the solid content concentration of the PEDOT/PSS is set to 2.8% and the rotation frequency of the substrate is set to 800 rpm for 5 sec, further, 2000 rpm for 20 sec as the condition for forming the hole transporting layer 18a having a film thickness of 110 nm.

Next, the inter-layer 18c having a film thickness of 10 nm is formed by the spin cost method by dropping the xylene solution having concentration of 0.5 wt % on the hole transporting layer 18a and by setting the rotation frequency to 800 rpm for 5 sec, further to 2000 rpm for 20 sec as the condition for film forming.

Subsequently, the blue luminescence layer (or electron transporting light emitting layer) 18b having a film thickness of 70 nm is formed by the spin cost method by dropping the xylene solution having concentration of 0.1 wt % on the inter-layer 18c and by setting the rotation frequency to 800 rpm for 5 sec, further to 2000 rpm for 20 sec as the condition for film forming.

Thereafter, after the electron injection layer 19a is formed by the vacuum-deposition method on the blue luminescence layer 18b by forming a film of calcium (Ca) in a film thickness of 15 nm, the transparent electrode layer 19b is formed by the counter target spatter method by forming a film of the ITO in a film thickness of 50 nm.

Then, the sealing layer 20 is formed by the counter target spatter method by forming a film of nitride silicon in a film thickness of 600 nm as the passivation film.

In the organic EL element in which each layer having the above described film thicknesses, the chromaticity characteristic (chromatic coordinate) at the time of light emission was verified.

When the film thickness of the hole transporting layer 18a is set to 25 nm, the CIE (Commission International de l'Eclairage; International Commission on Illumination) xy chromatic coordinate in the observation result is CIE (0.207, 0.380) and the CIE xy chromatic coordinate in the simulation result is CIE (0.163, 0.392) as shown in FIG. 20A.

Moreover, when the film thickness of the hole transporting layer 18a is set to 50 nm, the CIE xy chromatic coordinate in the observation result is CIE (0.230, 0.452) and the CIE xy chromatic coordinate in the simulation result is CIE (0.186, 0.474) as shown in FIG. 20B.

That is, in either of the cases where the film thickness of the hole transporting layer 18a is set to 25 nm and where the film thickness of the hole transporting layer 18a is set to 50 nm, the luminescent chromaticity is greatly shifted from the chromatic region of blue (B) color and it is found that the blue luminescent is not carried out in a good condition.

On the other hand, when the film thickness of the hole transporting layer 18a is set to 90 nm, the CIE xy chromatic coordinate in the observation result is CIE (0.145, 0.085) and the CIE xy chromatic coordinate in the simulation result is CIE (0.133, 0.083) as shown in FIG. 21A.

Further, when the film thickness of the hole transporting layer 18a is set to 110 nm, the CIE xy chromatic coordinate in the observation result is CIE (0.138, 0.101) and the CIE xy chromatic coordinate in the simulation result is CIE (0.128, 0.103) as shown in FIG. 21B.

That is, in either of the cases where the film thickness of the hole transporting layer 18a is set to 90 nm and where the film thickness of the hole transporting layer 18a is set to 110 nm, the coordinate which shows clear blue is within the chromatic region of blue (B) color and it is found that the blue luminescent is carried out in a good condition.

Such change the luminescent chromaticity due to the film thickness of the hole transporting layer 18a occurs based on the interference effect which is due to the light path difference (difference in the optical length) between the light RY1 and the light RY2 which are shown in FIG. 19B in the element structure shown in FIG. 19A. Here, the light RY1 is light emitted without passing through the hole transporting layer which is emitted at the luminous point in the blue luminescence layer (electron transporting light emitting layer) 18b and which passes the counter electrode 19 constituted of the transparent electron injection layer 19a and the transparent electrode layer 19b in the thickness direction and is directly emitted in the visual field side (upper direction in the drawing). Further, the light RY2 is light emitted by passing through the hole transporting layer 18a in which the film thickness is changed which is emitted in the visual field side (upper direction in the drawing) after repeatedly being reflected (multiple reflection is carried out) at the surface of the counter electrode 19 or the surface of the sealing layer 20 in the upper side of the luminous point and at the surface of the transparent electrode layer 15b or the surface of the reflection layer 15a of the pixel electrode 15 at the lower side of the luminous point. Therefore, the optimum luminescent chromaticity can be set on the CIE chromaticity diagram by arbitrarily adjusting the film thickness of the hole transporting layer 18a.

Further, as shown in FIGS. 20A, 20B and FIGS. 21A, 21B, as for the CIE xy chromatic coordinates in the case where the film thickness of the hole transporting layer 18a is changed within the range of 25 to 110 nm, it is found that the observation result when the organic EL element is actually prepared and the simulation result based on various types of parameters in the organic EL element are very close to one another. From this, it is found that the chromaticity characteristic (chromatic coordinate) when the light is emitted can be decided with relatively high accuracy based on the various types of parameters in the organic EL element.

Hereinafter, as for the chromaticity characteristic (chromatic coordinate) at the time of light emission in the organic EL elements which respectively emits green light and red light, description is given by only showing the simulation results based on various types of parameters. Here, in a similar manner as in the above described case of the organic EL element which emits blue light, it is considered that the organic EL elements which respectively emits green light and red light have the element structure shown in FIG. 19A.

When the chromaticity characteristic (simulation result) at the time of light emission is verified for the organic EL element which emits green light, the CIE xy chromatic coordinate is CIE (0.439, 0.551) when the film thickness of the hole transporting layer 18a is set to 25 nm and the CIE xy chromatic coordinate if CIE (0.241, 0.711) when the film thickness is set to 110 nm as shown in FIG. 22A.

Moreover, when the chromaticity characteristic (simulation result) at the time of light emission is verified for the organic EL element which emits red light, the CIE xy chromatic coordinate is CIE (0.688, 0.310) when the film thickness of the hole transporting layer 18a is set to 25 nm and the CIE xy chromatic coordinate if CIE (0.426, 0.288) when the film thickness is set to 110 nm as shown in FIG. 22B.

In such way, it is found that the luminescent chromaticity changes according to the film thickness of the hole transporting layer 18a in the organic EL elements which respectively emit green light and red light similarly to the above described case of the organic EL element which emits blue light.

Based on this, the optimum luminescent chromaticity of the blue light, green light and red light can be set on the CIE chromaticity diagram as shown in FIG. 23 by arbitrarily adjusting the film thickness of the hole transporting layer 18a in the organic EL element having the element structure shown in FIG. 19A.

In particular, as an example of the film thickness of the hole transporting layer 18a, the chromatic coordinate could be set to CIE (0.133, 0.083) by setting the film thickness of the hole transporting layer 18a to 90 nm in the organic EL element which emits blue light. In the organic EL element which emits green light, the chromatic coordinate could be set to CIE (0.179, 0.744) by setting the film thickness of the hole transporting layer 18a to 95 nm. In the organic EL element which emits red light, the chromatic coordinate could be set to CIE (0.691, 0.307) by setting the film thickness of the hole transporting layer 18a to 15 nm. These are the coordinates which show clear luminescent colors in each chromaticity region of blue (B) color, green (G) color and red (R) color, and it is found that the blue luminescence, the green luminescence and the red luminescence can be carried out in good conditions.

In such way, according to the display apparatus and the manufacturing method thereof according to the embodiment, the hole transporting layer can be set to have an arbitrary film thickness for each luminescent color and the hole transporting layer can be formed by having an even film thickness and a good flatness. Therefore, the optical length of the light which is emitted form the luminous point can be adjusted to be optimal for each luminescent color, and further, the chromaticity adjustment and the emission intensity can be easily adjusted by suppressing the shifting of chromaticity and dispersion of the light emitting brightness due to the interference effect. Thus, a display apparatus having a good display property without running and blurring of the image can be realized.

Moreover, as shown in FIGS. 19A and 19B to FIGS. 22A and 22B, the luminescent color of an arbitrary coordinate on the CIE chromaticity diagram can be realized by changing the film thickness of a specific layer (hole transporting layer) which forms the organic EL layer 18. Therefore, for example, the color tone can be changed so as to emit red light by increasing the composition of the broad wavelength range by the interference effect in the organic EL element which emits green light by adjusting the film thickness of the hole transporting layer.

Alternatively, the color tone can be changed so as to emit red light, green light or blue light in the organic EL element having the light emitting layer of the same color by adjusting the film thickness of the hole transporting layer in the organic EL element having a specific luminescent color, for example, in the organic EL element which emits white light.

Here, in the above described embodiment, a case where the organic EL layer 18 is constituted of the hole transporting layer 18a having different film thicknesses for each color of RGB and the electron transporting light emitting layer having a predetermined film thickness, the PEDOT/PSS is applied as the organic compound containing solution for forming the hole transporting layer 18a, and the light emitting material solution including polyphenylenevinylene polymer as the organic compound containing solution for forming the electron transporting light emitting layer 18b is described. However, the present invention is not limited to this. That is, the layer having different film thickness for each color is not limited to the above described hole transporting layer 18a, and the inter-layer 18c or a plurality of layers of the hole transporting layer 18a and the inter-layer 18c which are shown in FIG. 19A, for example, may be applied as long as the layer allows the light emitted from the light emitting layer which is the luminous point pass through (that is, the layer is on the light path). Further, the layer having different film thickness for each color may be a layer in which the organic EL layer 18 only has the hole transporting/electron transporting light emitting layer having different film thickness for each color may be a layer in which the organic EL layer 18 has the hole transporting light emitting layer and the electron transporting layer having different film thickness for each color. Furthermore, the layer having different thickness for each color may be a layer in which the carrier transporting layer other than the inter-layer is arbitrarily inserted between each layer. Moreover, a solution having another composition may be preferably applied as the organic compound containing solution for forming the organic EL layer 18 as long as the solution includes the hole transporting material, the electron transporting light emitting material and the like and as long as the applying of the solution can be carried out.

Moreover, in the above described embodiment, a case where the pixel electrode 15 is an anode electrode of organic EL element and the counter electrode 19 is a cathode electrode and where the hole transporting layer 18a is formed in the pixel electrode 15 side and the electrode transporting light emitting layer 18b is formed in the counter electrode 19 side is described. However, the present invention is not limited to this, and the pixel electrode 15 may be a cathode electrode of organic EL element and the counter electrode 19 may be an anode electrode. In such case, the element structure will be such that the electron transporting light emitting layer 18b is formed in the pixel electrode 15 side and that the hole transporting layer 18a is formed in the counter electrode 19 side.

Further, in the above described embodiment, the display panel having the top emission type light emitting structure in which the light from the light emitting layer is emitted in the visual field side of one surface side of the insulation substrate without allowing the light to pass through the insulation substrate is described. However, the present invention is not limited to this, and the display panel may have the bottom emission type light emitting structure in which the light from the light emitting layer is emitted in the visual field side of the other surface side of the insulative substrate by allowing the light to pass through the insulative substrate. In such case, the pixel electrode is to be formed with a conductive material having the light transparency characteristic such as the ITO and the counter electrode is to be formed with a conductive material having the light reflecting characteristic such as aluminum, chromium or the like.

The entire disclosure of Japanese Patent Application No. 2007-340226 filed on Dec. 28, 2007 including descriptions, claims, drawings, and abstracts are incorporated herein by reference in its entirety.

Although various typical embodiments have been shown and described, the present invention is not limited to those embodiments. Consequently, the scope of the present invention can be limited only by the following claims.

What is claimed is:

1. A manufacturing method of a display apparatus in which a plurality of display pixels comprising light emitting elements each of which has any one of a plurality of luminescent colors which carry out a color display are arranged along a plurality of rows and along a plurality of columns on a substrate, the manufacturing method comprising:
a step of applying a light emitting material solution for forming a light emitting function layer of the light emitting elements having each of the luminescent colors to a light emitting element forming region on the substrate,
the step of applying the light emitting material solution includes a step of applying the light emitting material solution in which the light emitting elements of a plurality of columns are formed, in an order that the light emitting material solution is not continuously applied to the light emitting element forming regions in adjacent columns among the plurality of columns and in an applying amount which is set so as to correspond to each of the luminescent colors.

2. The manufacturing method according to claim 1, wherein
the step of applying the light emitting material solution includes a step of applying simultaneously the light emitting material solution for forming the light emitting function layer of the light emitting elements having a same luminescent color to the light emitting element forming regions in a predetermined number of columns which are spaced apart on the substrate.

3. The manufacturing method according to claim 1, wherein
the step of applying the light emitting material solution includes a step of setting the applying amounts of the light emitting material solution for forming the light emitting function layers of the light emitting elements having at least two different luminescent colors so that the applying amounts be different for each of the luminescent colors.

4. The manufacturing method according to claim 3, wherein
the step of applying the light emitting material solution includes a step of applying the light emitting material solution to the light emitting element forming region continuously in one column along an extending direction of the one column.

5. The manufacturing method according to claim 4, wherein
the step of applying the light emitting material solution includes a step of applying the light emitting material solution to the light emitting element forming region in each column along the extending direction of the each column at a fixed speed, and
the step of applying the light emitting material solution at a fixed speed includes a step of setting amounts per unit time of the light emitting material solution to be applied so that the amounts per unit time of the light emitting material solution for forming the light emitting function layers of the light emitting elements of at least two different luminescent colors be different for each of the luminescent colors.

6. The manufacturing method according to claim 4, wherein
the step of applying the light emitting material solution includes a step of applying the light emitting material solution in the extending direction of each column by setting an amount per unit time of the light emitting material solution to be applied to the light emitting element forming region of the each column to a fixed value, and
the step of applying the light emitting material solution by a fixed amount includes a setting of speeds of applying the light emitting material solution in the extending direction of the each column so that the speeds of applying the light emitting material solution for forming the light emitting function layers of the light emitting elements of at least two different luminescent colors be different for each of the luminescent colors.

7. The manufacturing method according to claim 4, wherein
the step of applying the light emitting material solution includes a step of applying the light emitting material solution for forming the light emitting function layers of the light emitting elements having at least two different luminescent colors to the light emitting element forming region in each column repeatedly in a different number of times for each of the luminescent colors, the different number of times being one time or a plurality of times.

8. The manufacturing method according to claim 1, wherein
the light emitting function layer includes a carrier transporting layer constituted of either one of a hole transporting layer or an electrode transporting layer, and
the step of applying the light emitting material solution includes a step of setting applying amounts of a liquid for forming the carrier transporting layer in the light emitting material solution so that film thicknesses of the carrier transporting layers of the light emitting function layers of the light emitting elements having at least two different luminescent colors be different for each of the luminescent colors.

9. The manufacturing method according to claim 1, wherein
the light emitting function layer includes an inserting layer having an electron blocking characteristic, and
the step of applying the light emitting material solution includes a step of setting applying amounts of a liquid for forming the inserting layer in the light emitting material solution so that film thicknesses of the inserting layers of the light emitting functions layers of the light emitting elements having at least two different luminescent colors be different for each of the luminescent colors.

10. The manufacturing method according to claim 1, wherein
the plurality of columns are divided into a plurality of column groups which are constituted of a plurality of columns which are spaced apart, and
the step of applying the light emitting material solution includes a specific color applying step of applying the light emitting material solution for forming the light emitting function layer of the light emitting elements having one specific luminescent color which is any one of the plurality of luminescent colors to the light emitting element forming region on the substrate in each column in a specific column group which is any one of the plurality of column groups, and
a step of repeating an operation to execute the specific color applying step to all of the column groups by changing the specific column group to another column group and by changing the specific luminescent color to another luminescent color every time when the specific color applying of the light emitting material solution to the light emitting element forming regions in all of the columns in the specific column group is finished.

11. A manufacturing apparatus for manufacturing a display apparatus in which a plurality of display pixels comprising light emitting elements each of which has any one of a plurality of luminescent colors which carry out a color display are arranged along a plurality of rows and along a plurality of columns on a substrate, the manufacturing apparatus comprising:
an applying device having at least one nozzle for discharging a light emitting material solution which forms a light emitting function layer of light emitting elements of each of the luminescent colors, and
a moving device for moving either one of the applying device or the substrate in a row direction or in a column direction of the substrate, wherein
the moving device moves the applying device in the row direction and moves the applying device to each column which are spaced apart among the plurality of columns on the substrate and moves the applying device along an extending direction of each column,
the applying device discharges the light emitting material solution from the nozzle in a discharging amount which is set so as to correspond to each of the luminescent colors to apply the light emitting material solution to a light emitting element forming regions of each column in a predetermined applying order while moving along an extending direction of each column by the moving device,
the applying order is set in an order that the light emitting material solution is not continuously applied to the light emitting element forming regions in adjacent columns among the plurality of columns.

12. The manufacturing apparatus according to claim 11, wherein
the applying apparatus has a predetermined number of nozzles, the predetermined number being two or more, and each of the nozzles are respectively disposed so as to correspond to the columns which are spaced apart on the substrate, and the applying device applies the light emitting material solution for forming the light emitting function layers of a same luminescent color to the light emitting element forming regions in a number of columns corresponding to the number of nozzles which are spaced apart on the substrate.

13. The manufacturing apparatus according to claim 11, wherein
the plurality of columns are divided into a plurality of column groups which are constituted of a plurality of columns which are spaced apart, and
the moving device moves the applying device to each column of a specific column group which is any one of the plurality of column groups on the substrate, and the applying device applies the light emitting material solution for forming the light emitting function layer of the light emitting elements of one specific luminescent color which is any one of the plurality of luminescent color to the light emitting element forming region of the each column, and
the moving device moves the applying device to another column group which is different from the specific column group every time when the light emitting material solution is finished being applied by the applying device to the light emitting element forming regions in all of the columns of the specific column group, and the applying device repeats an operation of applying the light emitting material solution for forming the light emitting function layer of the light emitting elements having another luminescent color which is different from the specific luminescent color to the light emitting element forming region of each column of the column group to all of the column groups.

14. The manufacturing apparatus according to claim 11, wherein
an amount per unit time of the light emitting material solution which is discharged from the nozzle by the applying device is set so as to be different for the light emitting material solution for forming the light emitting function layers of the light emitting elements having at least two different luminescent colors, and
a speed for moving the applying device along the extending direction of the each column by the moving device is set to a fixed speed.

15. The manufacturing apparatus according to claim 11, wherein
an amount per unit of the light emitting material solution which is discharged from the nozzle by the applying device is set to a fixed value, and
a speed for moving the applying device along the extending direction of the each column by the moving device is set so as to be different for the light emitting material solution for forming the light emitting function layers of the light emitting elements having at least two different luminescent colors.

16. The manufacturing apparatus according to claim 11, wherein
the moving device repeatedly moves the applying device to the light emitting element forming region in a same column for one time or a plurality of times and sets the applying device to apply the light emitting material solution to the light emitting element forming region in each column for one time or a plurality of times, and
a number of time to apply the light emitting material solution to the light emitting element forming region of the each column is set so as to be different for the light emitting material solution for forming the light emitting function layers of the light emitting elements having at least two different luminescent colors.
